(19) United States
(12) Patent Application Publication
(10) Pub. No.: US 2026/0212082 A1
(43) Pub. Date: Jul. 23, 2026

(54) DATA-DRIVEN SIMULATION AND ANALYSIS FRAMEWORK FOR MULTI-MODAL URBAN MOBILITY SYSTEMS

(71) Applicant: Cornell University, Ithaca, NY (US)

(72) Inventors: Timur Dogan, Ithaca, NY (US); Samitha Samaranayake, Ithaca, NY (US); Yang Yang, Ithaca, NY (US)

(21) Appl. No.: 19/139,935

(22) PCT Filed: Dec. 19, 2023
(86) PCT No.: PCT/US2023/084758

§ 371 Date: Jun. 17, 2025

Related U.S. Application Data
(60) Provisional application No. 63/433,527, filed on Dec. 19, 2022.

(51) Int. Cl. G06F 30/27

(52) U.S. Cl. CPC G06F 30/27

(57) ABSTRACT

An apparatus in an illustrative embodiment comprises a processing platform that includes at least one processing device, the processing device comprising a processor coupled to a memory. The processing platform is configured to implement a machine learning based framework for at least one of simulation and analysis relating to multi-modal mobility, the machine learning based framework comprising a plurality of stages, including at least a population synthesis stage and a trip generation stage. The processing platform is further configured to execute a first machine learning model in the population synthesis stage, and to execute a second machine learning model in the trip generation stage, the second machine learning model being different than the first machine learning model. The first machine learning model illustratively comprises a traveler cluster classifier, and the second machine learning model illustratively comprises a mode-duration choice model.

### RELATED APPLICATION

The present application claims priority to U.S. Provisional Patent Application Ser. No. 63/433,527, filed Dec. 19, 2022 and entitled “Data-Driven Simulation and Analysis Framework for Multi-Modal Urban Mobility Systems,” which is incorporated by reference herein in its entirety.

### STATEMENT REGARDING FEDERALLY SPONSORED RESEARCH OR DEVELOPMENT

This invention was made with government support under contract number 69A3551747119 awarded by The United States Department of Transportation. The government has certain rights in the invention.

### FIELD

The field relates generally to information processing systems, and more particularly to mobility simulation and/or analysis techniques in such systems.

### BACKGROUND

Simulating population-level multi-modal mobility patterns is useful in a wide range of applications such as traffic forecasting, environmental analysis, and epidemic simulation. It can also inform mobility-related decision-making by planners, urban designers, developers, and business owners about where to deploy new services, amenities, infrastructure, and interventions in the built environment. Existing simulation frameworks and tools, such as activity-based models and their relevant tools, are computationally costly and require complex configurations and expert knowledge to set up.

### SUMMARY

Illustrative embodiments disclosed herein provide data-driven simulation and analysis frameworks for multi-modal urban mobility systems. Such simulation and analysis frameworks in some embodiments address and overcome one or more of the above-noted drawbacks of conventional approaches.

For example, exemplary frameworks in some embodiments advantageously empower a broader array of stakeholders to make effective mobility-aware decisions. One or more such frameworks can be easily integrated into fast-paced decision-making processes such as design. Moreover, such frameworks in some embodiments provide simpler model architectures, compute results quickly, and require little to no domain knowledge so that non-experts can use them safely and effectively.

A given such framework illustratively provides simulation and/or analysis functionality in urban multi-modal mobility contexts, illustratively involving urban mobility systems involving multiple distinct modes of transportation, including but not limited to walking, cycling, driving and public transit. However, it is to be appreciated that the disclosed frameworks are adaptable to numerous additional or alternative contexts.

An apparatus in an illustrative embodiment comprises a processing platform that includes at least one processing device, the processing device comprising a processor coupled to a memory. The processing platform is configured to implement a machine learning based framework for at least one of simulation and analysis relating to multi-modal mobility, the machine learning based framework comprising a plurality of stages, including at least a population synthesis stage and a trip generation stage. The processing platform is further configured to execute a first machine learning model in the population synthesis stage, and to execute a second machine learning model in the trip generation stage, the second machine learning model being different than the first machine learning model.

In some embodiments, the first machine learning model illustratively comprises a traveler cluster classifier, and the second machine learning model illustratively comprises a mode-duration choice model, although additional or alternative machine learning models could be used in other embodiments.

In some embodiments, the machine learning based framework further comprises a schedule synthesis stage arranged between the population synthesis stage and the trip generation stage, and/or a metric evaluation stage following the trip generation stage. Other types of stages can be used in other embodiments.

It is to be appreciated that the foregoing arrangements are only examples, including examples of potential applications of the disclosed techniques, and numerous alternative arrangements are possible.

These and other illustrative embodiments include but are not limited to systems, methods, apparatus, processing devices, integrated circuits, and computer program products comprising processor-readable storage media having software program code embodied therein.

### BRIEF DESCRIPTION OF THE FIGURES

FIG. 1 is a flow diagram of a process in an example data-driven simulation and analysis framework for multi-modal urban mobility systems in an illustrative embodiment.

FIG. 2 illustrates an example training process for a traveler cluster classifier implemented in a population synthesis stage of the embodiment of FIG. 1.

FIG. 3 illustrates an example training process for a mode-duration choice model implemented in a trip generation stage of the embodiment of FIG. 1.

FIG. 4 shows an information processing system comprising a data-driven simulation and analysis framework for multi-modal urban mobility systems in an illustrative embodiment.

FIG. 5 shows an overview of an example clustering and estimation framework in an illustrative embodiment.

FIG. 6 shows an example of a temporal mobility choice matrix for a particular socio-demographic profile in the clustering and estimation framework of FIG. 5 in an illustrative embodiment.

FIG. 7 shows examples of modified temporal mobility choice matrices in the clustering and estimation framework of FIG. 5 in an illustrative embodiment.

FIG. 8 is a graph of feature importance rankings for an example cluster membership classifier in an illustrative embodiment.

FIG. 9 shows census block group router points and accessible census block groups within different walking duration levels from a particular census block group in an illustrative embodiment. This figure includes three distinct parts denoted (a), (b) and (c).

FIG. 10 is a graph of feature importance rankings for an example mode-duration choice model in an illustrative embodiment.

FIG. 11 illustrates the operation of another example data-driven simulation and analysis framework for multi-modal urban mobility systems in an illustrative embodiment.

FIGS. 12A through 12F illustrate respective models utilized in the data-driven simulation and analysis framework of FIG. 11 in illustrative embodiments.

FIG. 13 shows pseudocode for an example algorithm for mapping blocks to grid points in buffer zones in an illustrative embodiment.

FIG. 14 shows examples of simulation configurations including modeling areas with and without buffer zones in illustrative embodiments.

### DETAILED DESCRIPTION

Illustrative embodiments can be implemented, for example, in the form of information processing systems comprising one or more processing platforms each having at least one computer or other processing device. A number of examples of such information processing systems will be described in detail herein. It should be understood, however, that embodiments of the present disclosure are more generally applicable to a wide variety of other types of information processing systems and associated processing devices or other components. Accordingly, the term “information processing system” as used herein is intended to be broadly construed so as to encompass these and other arrangements.

Simulating population-level multi-modal mobility patterns is useful in a wide range of applications such as traffic forecasting, environmental analysis, and epidemic simulation. It can also inform mobility-related decisions made by planners, urban designers, developers, and business owners regarding the optimal deployment of new services, amenities, infrastructure, and interventions in the built environment. Integration of simulation capabilities at the early stages of urban design and planning process is particularly important, as modifying established city structures can be prohibitively costly.

Microscopic simulation models, like activity-based travel demand models and agent-based simulations, are valuable tools for evaluating design and planning schemes due to their ability to capture intricate interactions among travel behavior, time, space, activities, and demographic characteristics. However, existing microscopic simulation frameworks and tools are computationally expensive, complex to configure, and lack adaptability for diverse multi-scale urban projects. These challenges combined make it difficult for designers and planners to seamlessly incorporate these simulation models into routine workflows, particularly in projects with limited resources and budgets.

There is a critical need for innovative microscopic simulation frameworks capable of modeling extensive human travel behaviors in an agile and adaptable manner, enabling broader applications requiring swift and iterative scenario testing. Illustrative embodiments disclosed herein address this need by providing such frameworks. It is expected that the disclosed frameworks will facilitate the adoption of mobility simulation across a wider spectrum of urban design and planning practices.

Some embodiments illustratively provide a multi-modal mobility simulation and analysis framework configured using data-driven, machine learning based techniques as disclosed herein. The framework in some embodiments comprises an integrated travel demand model system that includes a plurality of stages, illustratively including respective processing stages for population synthesis, daily schedule synthesis, trip generation, and metric evaluation. The framework in some embodiments includes at least two distinct machine learning models, illustratively comprising a traveler cluster classifier implemented in the population synthesis stage and a mode-duration choice model implemented in the trip generation stage. Other embodiments can include different types and arrangements of processing stages and/or machine learning models. For example, some embodiments implementing techniques disclosed herein can include only a traveler cluster classifier, or only a mode-duration choice model, and possibly also different arrangements of associated processing stages.

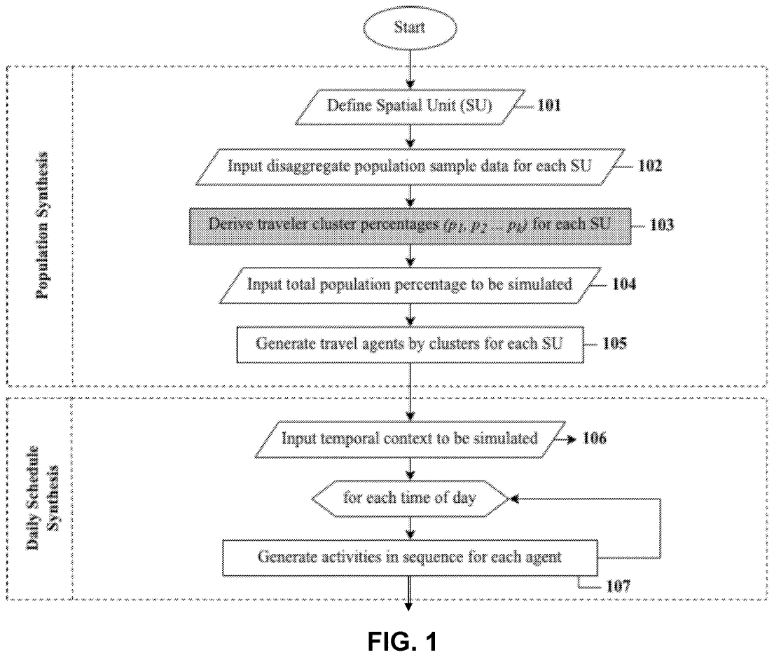

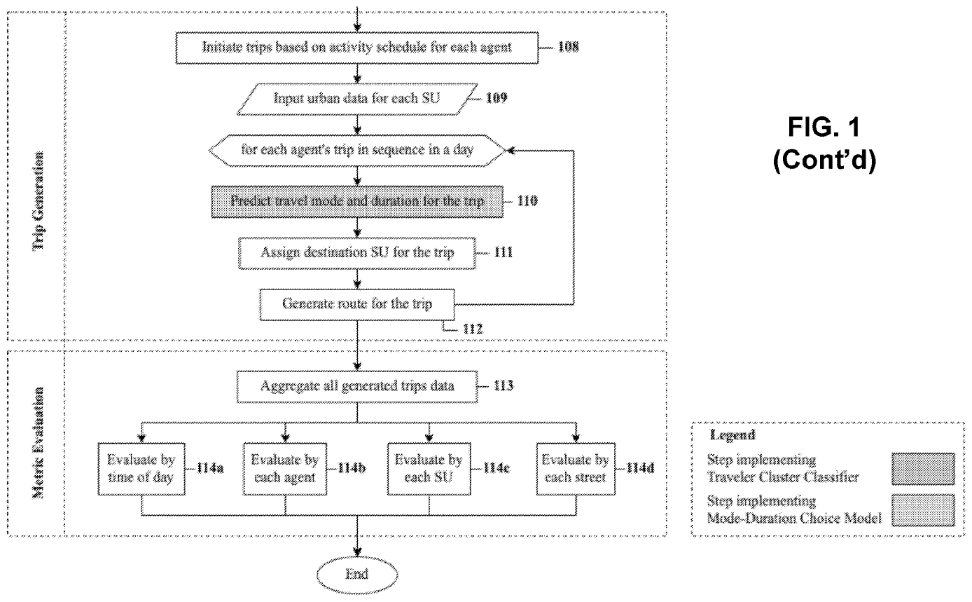

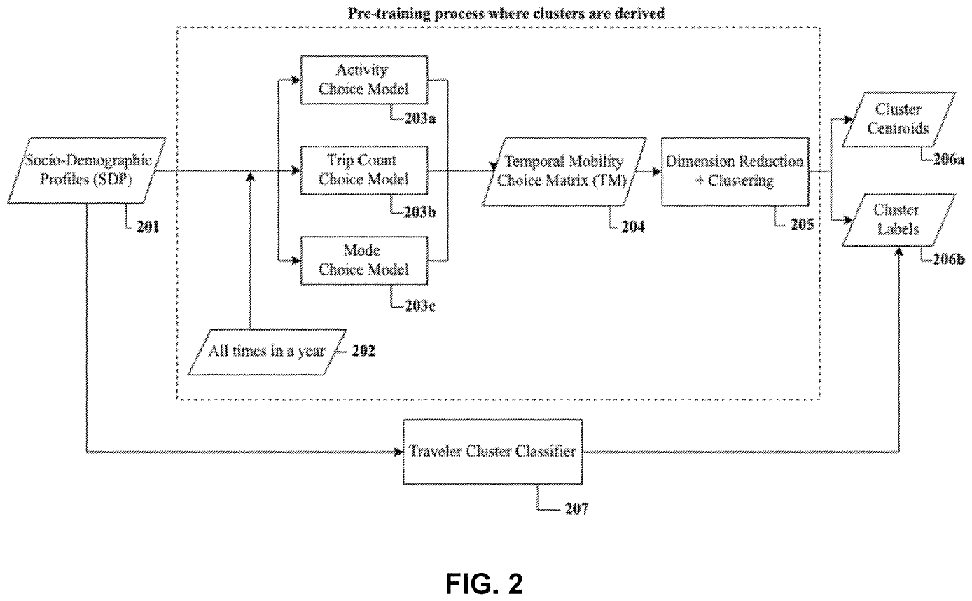

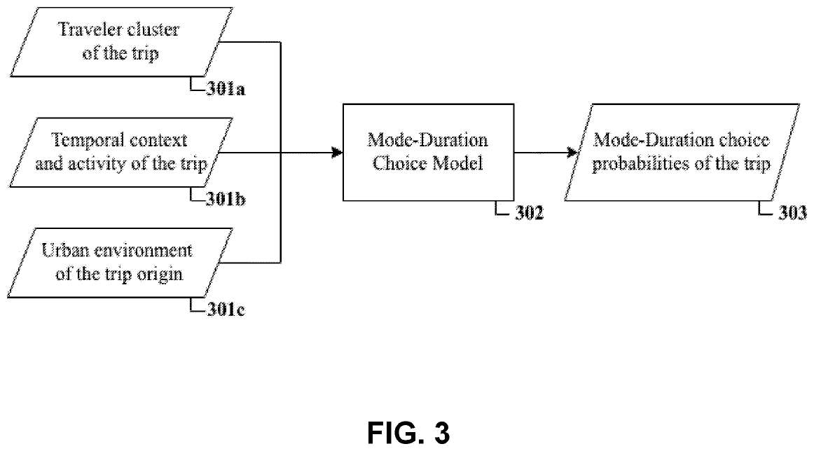

FIG. 1 illustrates a flow diagram of an example framework comprising the above-noted processing stages for population synthesis, daily schedule synthesis, trip generation, and metric evaluation, while FIGS. 2 and 3 illustrate aspects of the respective traveler cluster classifier and mode-duration choice model.

As will be described in more detail elsewhere herein, illustrative embodiments disclosed herein can provide reduced computation time compared to the traditional integrated travel demand model or activity-based model.

Additionally or alternatively, some embodiments provide enhanced flexibility in including new factors of interest in the modeling due to the data-driven nature of the framework. In some embodiments, to include new factors, one can simply add the new features to the training data and re-train the machine learning models.

Illustrative embodiments can be implemented as a stand-alone simulation tool, such as a mobility simulation plug-in (e.g., based on Rhino3D, Grasshopper and/or ArcGIS). Additionally or alternatively, some embodiments can be integrated into larger mobility models or solutions. For example, the machine learning models and one or more other portions of their respective stages of the framework can be used to replace certain components of existing travel demand modeling systems. Numerous other implementations of simulation and analysis frameworks as disclosed herein are possible, as will be appreciated by those skilled in the art. It should be understood that references herein to a “simulation and analysis framework” are intended to be broadly construed, so as to encompass, for example, frameworks that incorporate functionality for simulation and/or analysis.

Referring now to FIG. 1, the example framework as illustrated comprises a plurality of sequentially-arranged processing stages, including the above-noted processing stages for population synthesis, daily schedule synthesis, trip generation, and metric evaluation, with the population synthesis stage implementing a traveler cluster classifier, and the trip generation stage implementing a mode-duration choice model.

Although the stages are illustratively shown in FIG. 1 as being arranged sequentially relative to one another, in other embodiments, one or more of the stages may at least partially overlap with one or more other ones of the stages. Such embodiments support at least partially concurrent operation of two or more of the stages.

The population synthesis stage comprises steps 101 through 105 as shown, with step 103 implementing a traveler cluster classifier in this embodiment. The population synthesis stage illustratively aims to generate travel agents for each Spatial Unit (SU) specified in step 101. User input of disaggregate population sample data is performed in step 102. For example, this data could comprise Public Use Microdata Sample (PUMS) data provided by the U.S. Census Bureau, and/or other types of data. Step 103 derives traveler cluster percentages using a traveler cluster classifier, illustratively the traveler cluster classifier 207 of FIG. 2, to match each individual sample data to a cluster label 206b. The derived traveler cluster percentages can be represented by a vector as follows:

$$Traveler cluster percentages = ( {p}_{1} , {p}_{2} , … , {p}_{k} )$$

where pₖ is the percentage of the population that belongs to cluster k (i.e., Σpₖ=1). Then, given the user-specified total simulation population percentage (e.g., 10%) in step 104, travel agents by clusters can be generated in step 105.

The daily schedule synthesis stage comprises steps 106 through 107 as shown. Step 107 implements output 206a of the training process of the traveler clustering as shown in FIG. 2. In this stage, a user first specifies the temporal context in step 106, including the season and the weekday or weekend flag. Then, in step 107, the activities of each agent are generated in sequence for each time of day (e.g., early morning, morning, noon, afternoon, evening, and night). These activities are sampled based on the cluster centroid probability distribution of trip count and activity choice of the traveler's cluster.

The trip generation stage comprises steps 108 through 112. Step 110 implements aspects of the mode-duration choice model. The trip generation stage begins with step 108 which initiates trips based on the synthesized daily schedules. Each trip is initiated with a known traveler cluster, temporal context, and activity, which are predictors corresponding to inputs 301a and 301b for the mode-duration choice model as shown in FIG. 3. The user input data in step 109 provides the urban environment data as predictors for input 301c, allowing the mode-duration choice model to predict the mode and duration for any trip given that its origin SU is known. As a result, each agent's trips in a day are sequentially simulated regarding its choice of mode, duration, destination SU, and route, as shown in steps 110, 111 and 112.

The metric evaluation stage comprises steps 113 through 114, the latter more particularly comprising steps 114a, 114b, 114c and 114d, to evaluate by time of day, agent, SU and street, respectively. The metric evaluation stage starts with gathering all simulated trips in step 113. These trip data can be aggregated and evaluated at different dimensions, corresponding to respective steps 114a, 114b, 114c and 114d. These different metrics suit various types of use cases and applications.

The particular processing operations and other system functionality described in conjunction with the flow diagram of FIG. 1 are presented by way of illustrative example only, and should not be construed as limiting the scope of the disclosure in any way. Alternative embodiments can implement other types and arrangements of processing operations involving different processing stages and/or different machine learning models and their associated machine learning algorithms. For example, the ordering of the process steps may be varied in other embodiments, or certain steps may be performed at least in part concurrently with one another rather than serially. Also, one or more of the process steps may be repeated periodically, or multiple instances of the process can be performed in parallel with one another in order to implement a plurality of different simulation and analysis arrangements within a given information processing system.

Functionality such as that described in conjunction with the flow diagram of FIG. 1 can be implemented at least in part in the form of one or more software programs stored in memory and executed by a processor of a processing device such as a computer or server. As will be described below, a memory or other storage device having executable program code of one or more software programs embodied therein is an example of what is more generally referred to herein as a “processor-readable storage medium.”

FIG. 2 shows an example training process for a traveler cluster classifier in an illustrative embodiment. The process includes components 201 through 207 arranged as shown. Input 201 illustratively comprises socio-demographic profiles (SDPs) of the individual travelers from the training data. Each SDP is transformed into a temporal mobility choice matrix 204, also denoted as TM in the figure and elsewhere herein, through an activity choice model 203a, a trip count choice model 203b and a mode choice model 203c. A TM 204 contains mobility choice probabilities for a plurality of time windows 202. All TMs for all SDPs in the training data are processed through a dimension reduction and clustering process 205. The outputs of the clustering process illustratively include cluster centroids 206a, which may be representative mobility choice probabilities for each cluster, and cluster labels 206b for each input SDP. The traveler cluster classifier 207 can then be trained to link the input SDP and the output cluster labels 206b so that it can be used to predict the cluster label of any given SDP.

FIG. 3 shows an example training process for a mode-duration choice model in an illustrative embodiment. The model 302 receives inputs 301a, 301b and 301c, illustratively comprising a traveler cluster of a trip, a temporal context and activity of the trip, and an urban environment of the trip origin. The model 302 utilizes these applied inputs to generate an output 303 providing mode-duration choice probabilities of the trip as shown.

Additional details regarding aspects of the embodiments of FIGS. 1 to 3 can be found elsewhere herein.

It is to be appreciated that the particular arrangements of framework processing stages, machine learning models and other elements shown in FIGS. 1 through 3 are presented by way of illustrative example only, and numerous alternative embodiments are possible. For example, other types and arrangements of additional or alternative stages and/or additional or alternative machine learning models and their associated machine learning algorithms can be used.

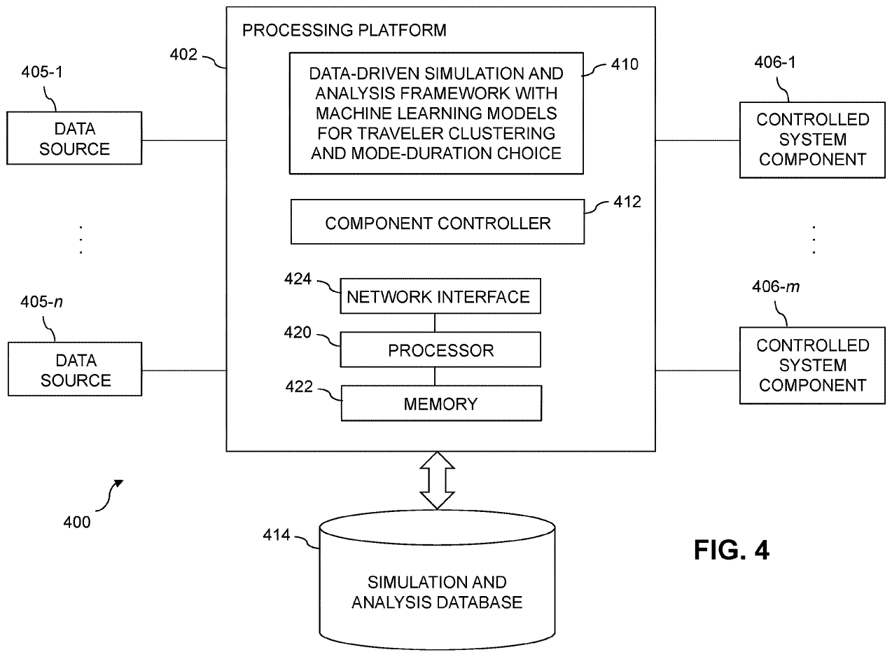

FIG. 4 shows an information processing system 400 implementing an example data-driven simulation and analysis framework in an illustrative embodiment. The system 400 comprises a processing platform 402. Coupled to the processing platform 402 are data sources 405-1, . . . 405-n and controlled system components 406-1, . . . 406-m, where n and m are arbitrary integers greater than or equal to two and may but need not be equal. Other embodiments can include only a single data source and/or only a single controlled system component. Additionally or alternatively, different ones of the data sources 405 and the controlled system components 406 may represent the same processing device, or different components of that same processing device, such as a computer, a mobile telephone (e.g., a “smartphone”), a vehicle-based system (e.g., an on-board navigation system, a driver assistance system and/or an autonomous vehicle control system) or another type of processing device associated with one or more system users.

The processing platform 402 comprises a data-driven simulation and analysis framework 410 and at least one component controller 412. The simulation and analysis framework 410 in the present embodiment more particularly implements one or more machine learning models, such as traveler cluster classifiers and/or mode-duration choice models of the type described elsewhere herein, although other arrangements are possible. The simulation and analysis framework 410 is an example of what is more generally referred to herein as a machine learning based framework, and illustratively comprises one or more machine learning systems each implementing one or more machine learning models.

In operation, the processing platform 402 is illustratively configured to obtain data from one or more of the data sources 405, and to process the obtained data using machine learning models for traveler clustering and mode-duration choice deployed in the simulation and analysis framework 410. As described in more detail elsewhere herein, the simulation and analysis framework 410 illustratively comprises one or more processing stages, such as the population synthesis stage, schedule synthesis stage, trip generation stage and/or metric evaluation stage of the example framework in the FIG. 1 embodiment.

The simulation and analysis framework 410 therefore in some embodiments illustratively implements the same processing stages, processing operations and machine learning models of FIGS. 1 through 3, although alternative arrangements of such components can be used in other embodiments.

The term “obtained data” as used herein is intended to be broadly construed, so as to encompass, for example, any of a wide variety of different types of input data that may be received from one or more of the data sources 405, which may include various types of computers, servers, networks, databases, sensors, cameras and/or other types of sources of one or more signals or other data, as well as metadata, descriptive information, contextual information, and/or other types of information associated with the one or more signals or other data, all or at least portions of which are intended to be encompassed by the broad term “obtained data” as used herein. Such components are examples of data sources 405, and additional or alternative data sources 405 can be used in other embodiments.

The processing platform 402 is further configured to generate in component controller 412 at least one control signal based at least in part on one or more outputs of the simulation and analysis framework 410. Additionally or alternatively, such a control signal may be generated within the simulation and analysis framework 410, and may comprise, for example, one or more outputs of a trip generation stage and/or a metric evaluation stage of the simulation and analysis framework 410.

The control signal in some embodiments is illustratively configured to trigger at least one automated action in at least one processing device that implements the processing platform 402, and/or in at least one additional processing device external to the processing platform 402. For example, the control signal may be transmitted over a network from a first processing device that implements at least a portion of the simulation and analysis framework 410 to trigger at least one automated action in a second processing device that comprises at least one of the controlled system components 406.

It is to be appreciated that the term “machine learning model” as used herein is intended to be broadly construed to encompass at least one machine learning algorithm configured using one or more machine learning techniques. More detailed examples of particular implementations of machine learning algorithms implemented by simulation and analysis framework 410 are described elsewhere herein.

The component controller 412 generates one or more control signals for adjusting, triggering or otherwise controlling various operating parameters associated with the controlled system components 406 based at least in part on predictions or other outputs generated by the simulation and analysis framework 410. A wide variety of different types of devices or other components can be controlled by component controller 412, possibly by applying control signals or other signals or information thereto, including additional or alternative components that are part of the same processing device or set of processing devices that implement the processing platform 402 and/or one or more of the data sources 405. Such control signals, and additionally or alternatively other types of signals and/or information, can be communicated over one or more networks to other processing devices, such as computers, mobile telephones, vehicle-based systems or other processing devices associated with one or more system users.

In some embodiments, the component controller 412 can be implemented within the simulation and analysis framework 410, rather than as a separate element of processing platform 402 as shown in the figure.

The processing platform 402 is configured to utilize a simulation and analysis database 414. Such a database illustratively stores a wide variety of different types of information, including, for example, data from one or more of the data sources 405, illustratively utilized by the simulation and analysis framework 410 in performing simulation and/or analysis in system 400. The simulation and analysis database 414 is also configured to store related information, including various processing results, such as predictions or other outputs generated by the simulation and analysis framework 410.

The component controller 412 utilizes outputs generated by the simulation and analysis framework 410 to control one or more of the controlled system components 406. The controlled system components 406 in some embodiments therefore comprise system components that are driven at least in part by outputs generated by the simulation and analysis framework 410. For example, a controlled system component can comprise at least one processing device, such as a computer, a mobile telephone, a vehicle-based system, or other processing device, configured to automatically perform a particular function in a manner that is at least in part responsive to an output of at least one machine learning system of a machine learning based framework. These and numerous other different types of controlled system components 406 can make use of outputs generated by the simulation and analysis framework 410, including various types of equipment and other systems associated with one or more of the example applications described elsewhere herein.

Although the simulation and analysis framework 410 and the component controller 412 are both shown as being implemented on processing platform 402 in the present embodiment, this is by way of illustrative example only. In other embodiments, the simulation and analysis framework 410 and the component controller 412 can each be implemented on a separate processing platform. A given such processing platform is assumed to include at least one processing device comprising a processor coupled to a memory.

Examples of such processing devices include computers, servers or other processing devices arranged to communicate over a network. Storage devices such as storage arrays or cloud-based storage systems used for implementation of simulation and analysis database 414 are also considered “processing devices” as that term is broadly used herein.

The network can comprise, for example, a global computer network such as the Internet, a wide area network (WAN), a local area network (LAN), a satellite network, a telephone or cable network, a cellular network such as a 4G or 5G network, a wireless network implemented using a wireless protocol such as Bluetooth, WiFi or WiMAX, or various portions or combinations of these and other types of communication networks.

It is also possible that at least portions of other system elements such as one or more of the data sources 405 and/or the controlled system components 406 can be implemented as part of the processing platform 402, although shown as being separate from the processing platform 402 in the figure.

For example, in some embodiments, the system 400 can comprise a laptop computer, tablet computer or desktop personal computer, a mobile telephone, a vehicle-based system, or another type of processing device, as well as combinations of multiple such processing devices, configured to incorporate at least one data source and to execute at least a portion of at least one machine learning system of a machine learning based framework for controlling at least one system component.

Examples of automated actions that may be taken in the processing platform 402 responsive to outputs generated by the simulation and analysis framework 410 include generating in the component controller 412 at least one control signal for controlling at least one of the controlled system components 406 over a network, generating control signals based on outputs of a trip generation stage and/or a metric evaluation stage of the simulation and analysis framework 410 for transmission to a device of a system user, generating at least a portion of at least one output display comprising analysis results for presentation on at least one user terminal, generating an alert for delivery to at least one user terminal over a network, and/or storing the outputs in the simulation and analysis database 414.

A wide variety of additional or alternative automated actions may be taken in other embodiments. The particular automated action or actions will tend to vary depending upon the particular application in which the system 400 is deployed.

Additional examples of applications are provided elsewhere herein. It is to be appreciated that the term “automated action” as used herein is intended to be broadly construed, so as to encompass the above-described automated actions, as well as numerous other actions that are automatically driven based at least in part on outputs of a machine learning based framework as disclosed herein.

The processing platform 402 in the present embodiment further comprises a processor 420, a memory 422 and a network interface 424. The processor 420 is assumed to be operatively coupled to the memory 422 and to the network interface 424 as illustrated by the interconnections shown in the figure.

The processor 420 may comprise, for example, a microprocessor, an application-specific integrated circuit (ASIC), a field-programmable gate array (FPGA), a central processing unit (CPU), a graphics processing unit (GPU), a tensor processing unit (TPU), an arithmetic logic unit (ALU), a digital signal processor (DSP), or other similar processing device component, as well as other types and arrangements of processing circuitry, in any combination. At least a portion of the functionality of a machine learning based framework and its associated machine learning models provided by one or more processing devices as disclosed herein can be implemented using such circuitry.

In some embodiments, the processor 420 comprises one or more graphics processor integrated circuits. Such graphics processor integrated circuits are illustratively implemented in the form of one or more GPUs. Accordingly, in some embodiments, system 400 is configured to include a GPU-based processing platform. Such a GPU-based processing platform can be at least partially cloud-based and configured to implement one or more machine learning systems for processing data associated with a large number of system users. Similar arrangements can be implemented using TPUs and/or other processing devices.

Numerous other arrangements are possible. For example, in some embodiments, a machine learning system can be implemented on a single processor-based device, such as a computer, a mobile telephone, a vehicle-based system or other processing device, utilizing one or more processors of that device. Such embodiments are also referred to herein as “on-device” implementations of machine learning systems. As indicated previously, a given machine learning based framework as disclosed herein can comprise multiple such machine learning systems, each implementing one or more machine learning models.

The memory 422 stores software program code for execution by the processor 420 in implementing portions of the functionality of the processing platform 402. For example, at least portions of the functionality of simulation and analysis framework 410 and component controller 412 can be implemented using program code stored in memory 422.

A given such memory that stores such program code for execution by a corresponding processor is an example of what is more generally referred to herein as a processor-readable storage medium having program code embodied therein, and may comprise, for example, electronic memory such as SRAM, DRAM or other types of random access memory, flash memory, read-only memory (ROM), magnetic memory, optical memory, or other types of storage devices in any combination.

Articles of manufacture comprising such processor-readable storage media are considered embodiments of the present disclosure. The term “article of manufacture” as used herein should be understood to exclude transitory, propagating signals.

Other types of computer program products comprising processor-readable storage media can be implemented in other embodiments.

In addition, illustrative embodiments may be implemented in the form of integrated circuits comprising processing circuitry configured to implement processing operations associated with one or both of the simulation and analysis framework 410 and the component controller 412 as well as other related functionality. For example, at least a portion of the simulation and analysis framework 410 is illustratively implemented in at least one neural network integrated circuit of a processing device of the processing platform 402.

The network interface 424 is configured to allow the processing platform 402 to communicate over one or more networks with other system elements, and may comprise one or more conventional transceivers.

It is to be appreciated that the particular arrangement of components and other system elements shown in FIG. 4 is presented by way of illustrative example only, and numerous alternative embodiments are possible. For example, other embodiments of information processing systems can be configured to implement machine learning based framework functionality of the type disclosed herein.

Terms such as “data source” and “controlled system component” as used herein are intended to be broadly construed. For example, a given set of data sources in some embodiments can comprise one or more computers, servers, cameras, sensors or other types of imaging or data capture devices, or combinations thereof, possibly associated with computers, mobile telephones, vehicle-based systems or other types and arrangements of user devices or other processing devices. Other examples of data sources include various types of databases or other storage systems accessible over a network. A wide variety of different types of data sources can be used to provide input data to a machine learning based framework such as simulation and analysis framework 410 in illustrative embodiments. A given controlled system component can illustratively comprise a computer, a mobile telephone, a vehicle-based system, or other processing device that receives an output from at least one machine learning system of a machine learning based framework and performs at least one automated action in response thereto. The machine learning based framework, its one or more machine learning systems and the given controlled system component can be part of the same processing device.

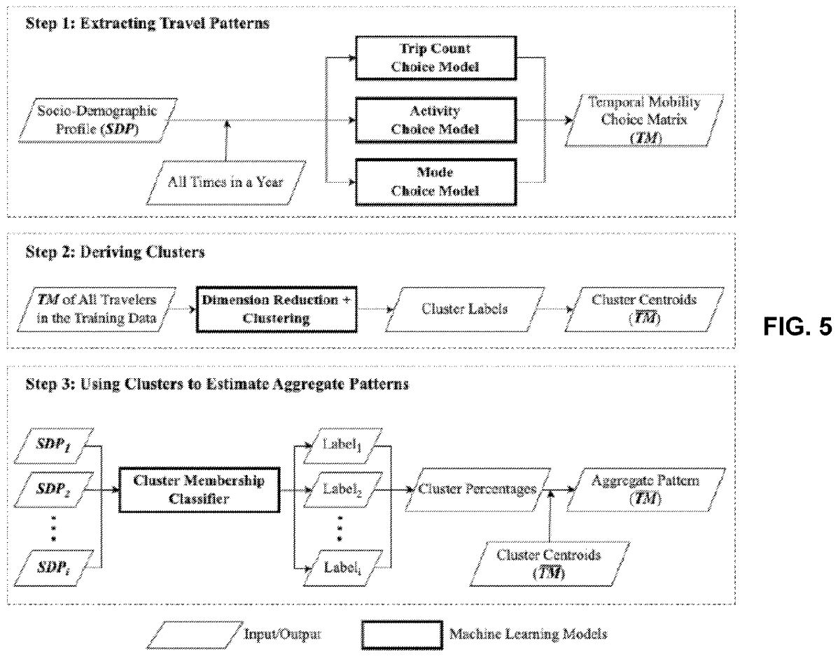

Additional details regarding illustrative embodiments are provided below with reference to FIGS. 5 through 14. The information processing systems, processing platforms, processing devices, networks, simulation and analysis frameworks, processing stages, machine learning models and other systems and components disclosed herein in conjunction with FIGS. 1 through 4 are illustratively configured in some embodiments to implement the example machine learning models and associated algorithms and other techniques that are described in detail with reference to FIGS. 5 through 14.

An example clustering-based approach to quantifying socio-demographic impacts on urban mobility patterns will now be described in more detail with reference to the embodiments of FIGS. 5 through 8. These embodiments provide a generalizable clustering approach to investigate the effects of socio-demographic features on aggregate urban mobility patterns, including activity distribution and travel modal split. Such embodiments more particularly use K-Means via Principal Component Analysis to identify eight representative traveler clusters from the 2017 U.S. National Household Travel Survey (NHTS). Based on the cluster centroids and the cluster percentages within a neighborhood, this example approach estimates a temporal mobility choice matrix (“TM”) that describes the neighborhood-level aggregate mobility choice pattern. The estimation accuracy is assessed in a case study in the City of Los Angeles (“LA City”). It is found that the neighborhood-level temporal mobility patterns are well-replicated, with an average R² of 65.47%, 53.15%, and 72.04% among all analyzed neighborhoods in the city. However, a moderate to low accuracy is found in estimating the spatial differences in the mobility patterns across neighborhoods. This could be because factors other than socio-demographics, such as physical and built environment factors like terrain, street quality, or amenity densities, are contributing to the spatial differences but have not been considered in the case study. Overall, this example approach shows that socio-demographic features alone can produce a good approximation of the average temporal mobility choice patterns of a given population. The example approach and corresponding results of these embodiments can serve as a baseline and benchmark for future mobility studies that take the socio-demographics of the traveler population into consideration in modeling.

Understanding the aggregate human mobility pattern is crucial for a wide range of urban studies such as carbon footprint estimates, environmental analysis, traffic forecasting, and epidemic simulation. It also informs urban planning and design decision-making about where to deploy infrastructure, services, and transportation-related interventions. While individual travel choices demonstrate significant uncertainties, travel patterns at the population level tend to have high regularity and can be explained mainly by a small set of representative patterns or factors. Researchers and decision-makers have been interested in reproducing aggregate human mobility patterns with accurate, generalizable, and easy-to-implement estimation models for decades, and this topic continues to gain attention in recent years with newly available data and modeling approaches.

Socio-demographic characteristics, such as income, gender, age, race, and occupation, are widely recognized to have direct impacts on individual and household travel choices. However, the combinatorial impacts of various socio-demographic characteristics on aggregate human travel patterns like activity distribution or modal split is still unclear. For instance, in a particular urban context, the residential demography can significantly impact the neighborhood-level travel modal split more than other factors, including properties of the built environment. Thus, it is imperative to understand how much socio-demographics influence urban mobility, what features are most impactful, and how they can be modeled and evaluated in a generalizable fashion. Illustrative embodiments address these and other issues.

As will become apparent, these embodiments provide a framework that examines socio-demographic impacts on aggregate human mobility patterns, including activity patterns and modal split, through travel population clustering. Based on the 2017 U.S. NHTS data, a matrix of travel choice patterns is synthesized over seasons, weekdays and weekends, and times of day for each possible SDP defined by selected personal and household features. Several representative traveler clusters are identified from the synthesized patterns, and the cluster centroids are computed. A machine learning classifier is trained to characterize cluster membership through socio-demographic features. With this classifier, accompanied by the disaggregate population sample data, cluster percentages of any given population can be derived. Then, the average mobility pattern of the population can be estimated as the weighted average of cluster centroids, weighted by cluster percentages. To assess the estimation accuracy, a case study is conducted in LA City where estimated results are compared against the observed patterns from a test dataset. These embodiments quantify the socio-demographic impacts on aggregate human mobility patterns to inform future urban mobility studies and modeling.

The training data in these embodiments includes socio-demographic data sourced from the 2017 U.S. NHTS, which contains 817082 trip records made by 227561 unique individuals after the data cleaning. The survey records each participant's personal and household characteristics and asks them to recall trips during the 24 hours prior to their survey day. All 365 days of the year are covered by different participants. Table 1 describes the selected socio-demographic features for these embodiments. A traveler's SDP is illustratively defined as a vector combining encoded 10 values for all features listed in Table 1.

TABLE 1
Description of socio-demographic data.

| Abbr. | Name | Type | Description/Levels (Percentage) |
|---|---|---|---|
| — | traveler ID | numerical | unique ID for the travel |
| | | | individual |
| AGE | age | numerical | years old (minimum = 5, |
| | | | maximum = 92) |
| RACE | race | categorical | 0 = others (5.8%); 1 = White |
| | | | (82.4%); 2 = Black or African |
| | | | American (7.2%); |
| | | | 3 = Asian (4.5%) |
| EDU | education | categorical | 0 = no bachelor's degree |
| | | | (55.6%); 1-with bachelor's |
| | | | degree or above (44.4%) |
| SEX | gender | categorical | 0 = female (53.1%); |
| | | | 1 = male (46.9%) |
| OCC | occupation | categorical | 0-others or no job (47.3%); |
| | | | 1 = sales or services (12.2%); |
| | | | 2 = clerical or administrative |
| | | | support (5.6%); 3 = |
| | | | manufacturing, construction, |
| | | | maintenance, or farming |
| | | | (6.9%); 4-professional, |
| | | | managerial, or technical |
| | | | (28.0%) |
| SCH | school | categorical | 0 = not enrolled in school |
| | enrollment | | (97.9%); 1 = enrolled |
| | | | in school (2.1%) |
| WRK | worker | categorical | 0-is not worker (45.1%); |
| | status | | 1 = is worker (54.9%) |
| HSZ | household | categorical | 1(17.5%), 2(46.0%), 3(16.2%), |
| | size | | 4(12.6%), 5 or more (7.6%) |
| HVH | household | categorical | 0(3.3%), 1(22.8%), 2(41.4%), |
| | vehicle | | 3 or more (16.2%) |
| | count | | |
| HINC | household | categorical | 0 = $35,000 or less (36%); |
| | income | | 1 = $35,000-$49,999 (18.0%); |
| | | | 2 = $50,000-$74,999 (14.4%); |
| | | | 3 = $75,000-$99,999 (11.5%); |
| | | | 4-$100,000-$124,999 (6.5%); |
| | | | 5-$125000 or more (13.6%) |
| HCH | household | categorical | 0 = not own child (75.7%); |
| | own child | | 1 = own child (24.3%) |
| HMSA | household | categorical | 0 = not in MSA or CMSA |
| | metropolitan | | (15.5%); 1 = in an MSA of less |
| | statistical | | than 250,000 population |
| | area | | (16.4%); 2 = in an MSA |
| | (MSA) size | | of 250,000-499,999 |
| | | | population (10.2%); |
| | | | 3 = in an MSA of 500,000- |
| | | | 999,999 (14.3%); 4 = in an |
| | | | MSA or CMSA of 1,000,000- |
| | | | 2,999,999 (15.0%); |
| | | | 5-in an MSA or CMSA |
| | | | of 3 million or |
| | | | more (28.7%) |
| HURB | household | categorical | 0 = in rural (23.4%); |
| | in urban | | 1 = in urban (76.6%) |
| HCD | household | categorical | 1 = New England (1.5%); |
| | census | | 2 = Middle Atlantic (14.4%); |
| | division | | 3 = East North Central (11.4%); |
| | | | 4 = West North Central |
| | | | (3.8%); 5 = South Atlantic |
| | | | (21.9%); 6 = East South Central |
| | | | (1.0%); 7 = West South Central |
| | | | (20.5%); 8 = Mountain |
| | | | (3.9%); 9 = Pacific (21.6%) |

The travel data includes travel information for each surveyed individual, including trip count, mode, time (season, weekday and weekend indicator, and the time of day), and activity (starting activity and destination activity), and is collected as shown in Table 2. This data can be 5 matched to Table 1 by the traveler ID.

TABLE 2
Description of travel data.

| Name | Type | Description/Levels (Percentage) |
|---|---|---|
| traveler ID | numerical | unique ID for the travel individual |
| trip count | numerical | total no. of trips that the traveler |
| | | takes during the specified time of |
| | | day, with a minimum of 0 and |
| | | a maximum of 5 |
| travel mode | categorical | walk (8.8%); bike (0.8%); vehicle |
| | | (87.1%); transit (1.2%); other |
| | | (2.1%) |
| Time | | |
| season | categorical | winter (December, January, February) |
| | | (25.7%); spring (March, April, May) |
| | | (20.8%); summer (June, July, August) |
| | | (26.8%); fall (September, October, |
| | | November) (26.7%) |
| weckend | categorical | Weekend (23.2%); weekday (76.8%) |
| time of day | categorical | Early morning (12 pm-6 am) (2.0%); |
| | | morning (6 am-11 am) (28.4%); |
| | | noon (11 am-3 pm) (29.9%); |
| | | afternoon (3 pm-5 pm) |
| | | (15.2%); evening (5 pm-9 pm) |
| | | (20.9%); night (9 pm-12 pm) |
| | | (3.6%) |
| Activity | | |
| starting | categorical | from home (33.8%); work |
| activity | | (11.9%); education (0.9%); |
| | | retail/errands (20.8%); recreation |
| | | (8.6%); food service (8.0%); |
| | | other (15.9%) |
| destination | categorical | to home (34.1%); work (11.8%); |
| activity | | education (0.9%); retail/errands |
| | | (20.8%); recreation (8.5%); food |
| | | service (8.0%); other (15.8%) |

In Table 2, trip count is a derived variable by counting the number of trip records associated with the traveler ID within each time window on the survey day of this person. The trip count numbers larger than 5 are considered outliers (0.8% of all data) and are replaced by 5.

FIG. 5 shows an overview of the clustering and estimation framework, which includes three steps, denoted Step 1, Step 2 and Step 3. Step 1 extracts travel patterns, Step 2 derives clusters, and Step 3 uses the clusters to estimate aggregate patterns. It is to be appreciated that additional or alternative steps can be used in other embodiments. This example framework utilizes a training dataset that combines the matched socio-demographic data (Table 1) and travel data (Table 2) to train several independent choice models that learn the time-sensitive travel choice patterns of every population profile.

In Step 1, the travel patterns are broken down into three levels of choices (i.e., activity, trip count, and travel mode) and a choice model is trained for each of them. For a given traveler with a specific SDP at a given time, these choice models can predict the probabilities regarding the number of trips the person makes, the type of activities at the origin and the destination, and the travel mode for each trip. By stacking the predicted probabilities for all possible times in a year, the TM is obtained.

In Step 2, the travelers are clustered based on their similarities in TM. Since TM is a large matrix that can impair the efficiency and accuracy of the clustering process if directly used for training, a dimension reduction technique is applied to this data before running the clustering. The direct output of clustering is the cluster label assigned to each individual traveler. This result is then used to obtain the representative patterns of each cluster, namely the cluster centroids, by taking the mean TM of each cluster (denoted as T̅M̅).

In Step 3, to estimate aggregate mobility patterns for a population, a disaggregate sample dataset that provides SDP for each sampled individual from the analyzed population is obtained. As shown, a cluster membership classifier that can assign a cluster label to any given SDP is trained. Based on all assigned labels within the sampled population, cluster percentages can be derived. The final aggregate pattern (denoted as [symbol] ) can be estimated as the weighted average of the cluster centroids, weighted by cluster percentages.

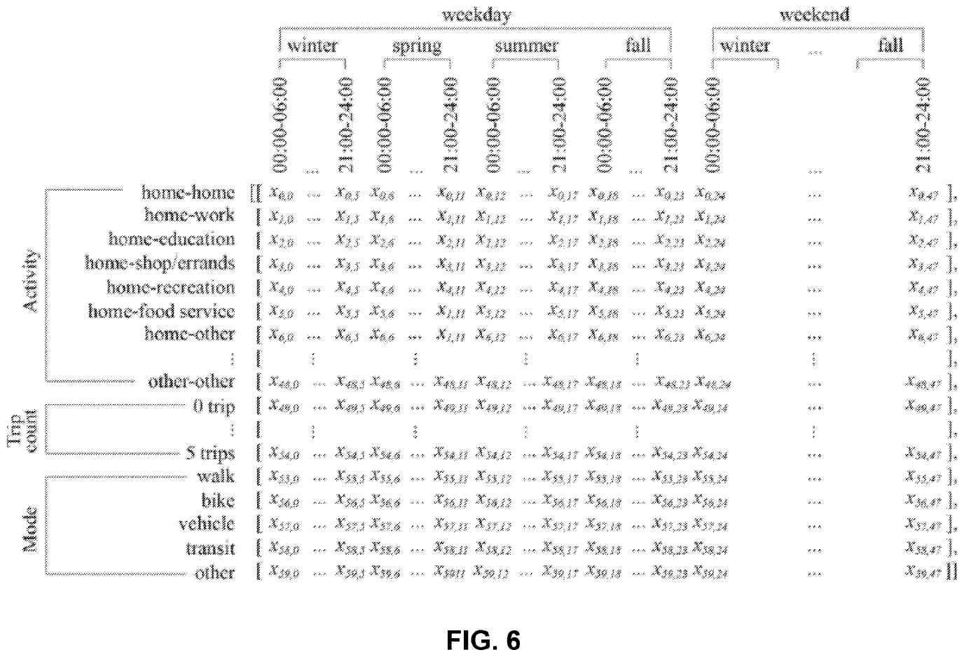

FIG. 6 shows an example format of the TM for one SDP. The TM is defined in FIG. 6 using 48 columns for all possible time windows. Each column combines three separate probability distributions regarding the traveler's choices of activity, trip count, and mode at the given time window

$$( i . e . , {\sum }_{i = 0}^{48} {x}_{i , j} = 1 , {\sum }_{i = 49}^{54} {x}_{i , j} = 1 , {\sum }_{i = 55}^{59} {x}_{i , j} = 1 ) .$$

For each type of choice, the probability distribution is predicted by one choice model that takes inputs of time features and the SDP. Although the actual decision logic of the trip count, activity, and mode may be interrelated, the choice models in the present embodiments are made independent of each other to simplify the formation of TM. Other types of choice models, including choice models that are not independent of each other, can be used.

The choice models in the present embodiments are defined as machine learning classification models which have the advantages of strong predictive power and simple set up. The classification models are trained through a five-fold cross-validation process during which the dataset is split into a different set of 80% training and 20% testing in each of the five iterations. The metric of aggregate-level goodness-of-fit is the L1 Norm as defined in Equation (1):

$${\sum }_{n}^{N} \vert {P}_{n} - {\hat{P}}_{n} \vert \qquad ( 1 )$$

where N is the number of choice options (i.e., N=49 for activity choice, 6 for trip count choice, and 5 for mode choice), \hat{P}ₙ is the average predicted probability of choice option n for all data samples, and Pₙ is the observed percentage of choice option n in the dataset. Multiple classification algorithms that can output probabilities, including Random Forest, AdaBoost, Naïve Bayes, and Multi-Layer Perceptron, are tested to select the best-performing model. Random Forest is selected for use in some embodiments herein, although it is to be appreciated that other types of classification algorithms can be used.

Clusters are then derived as follows. The TMs of all individuals from the dataset are stacked into a matrix as shown in Equation (2):

$$( \begin{matrix}{TM}_{{SDP}_{1}} \\ ⋮ \\ {TM}_{{SDP}_{227561}}\end{matrix} ) \qquad ( 2 )$$

where each row is a TM (flattened into a row vector with 2880 elements) for the individual's SDP. The number of rows is 227561, which is equal to the number of unique travelers in the training data. Note that duplicated SDP are not dropped because they contribute to the clustering weight.

These embodiments use K-Means via Principal Component Analysis as the clustering method, although other clustering methods can be used in other embodiments. The cluster centroid for cluster k, denoted as T̅M̅ₖ in Equation (3), is calculated as the average TM of all SDPs belonging to that cluster (represented by SDPᵢ∈k).

$${\overline{TM}}_{k} = \frac{{\sum }_{S D {P}_{i}} {TM}_{S D {P}_{i}}}{{\sum }_{S D {P}_{i} ∈ k} 1} \qquad ( 3 )$$

T̅M̅ₖ has the same format as shown in FIG. 6.

Illustrative embodiments use clusters to estimate aggregate pattern, as follows. The SDPs and cluster labels are linked with a cluster membership classifier that is trained using Random Forest. This approach is similar in some respects to a known decision-tree-based classifier referred to as CART, which has been used to link derived traveler clusters to a small set of socio-demographic variables. Random Forest is used in these embodiments rather than a simple decision tree classifier because there these embodiments include a large set of socio-demographic variables, and associated discrete levels, and Random Forest is more efficient to train on high-dimensional input data than CART. To calibrate the classifier, the five-fold cross-validation is conducted where the goodness-of-fit is measured as the percentage of correctly classified samples.

Using the identified clusters and the well-trained classifier, any group of travel population can be represented by a vector of cluster percentages as shown in Equation (4):

$$Cluster Percentages = [ {p}_{1} , {p}_{2} , … , {p}_{k} , … , {p}_{K} ] \qquad ( 4 )$$

where K is the number of clusters and pₖ is the percentage of the population that belongs to cluster k

$$( i . e . , {\sum }_{k = 1}^{K} {p}_{k} = 1 ) .$$

For any given neighborhood, cluster percentages can be derived from disaggregate population sample data where each sample can be matched to a cluster label. In the U.S., for example, this dataset illustratively comprises the 2017 PUMS dataset from the U.S. Census Bureau. It samples populations at the spatial resolution of the Public Use Microdata Sample Area (PUMA) and provides detailed individual-level socio-demographic data that is sufficient to derive a complete SDP. Thus, PUMA defines the neighborhoods for these embodiments.

The neighborhood-level aggregate pattern, denoted as [symbol] in Equation (5), is estimated as the weighted average of cluster centroids T̅M̅ₖ, weighted by the cluster percentage pₖ.

$$\text{?} = {\sum }_{k}^{K} {\overline{T M}}_{k} \cdot {p}_{k} \qquad ( 5 )$$

The estimation accuracy of the above-described approach was assessed using a case study conducted in LA City. The test data is sourced from the 2017 NHTS California Add-On data from Caltrans. This dataset contains additional travel survey samples for California which are not included in the national dataset for training. After cleaning and processing this data, 3675 trip records made by 852 unique travelers are obtained.

The estimation accuracy can be assessed by comparing the estimated aggregate pattern [symbol] for each neighborhood with the observations from the test data. However, the test sample size (852 unique travelers) is not large enough to sufficiently cover the entire choice space of TM for all neighborhoods, which would result in very sparse validation samples for certain choice options in some neighborhoods. To mitigate this problem, certain choice spaces are consolidated to allow more data samples to be used for deriving probabilities of each choice option. More specifically, for the activity pattern comparison, instead of using the probability distribution of the pair-wise activity choices (e.g., from home to work, from home to education), combined choices of starting activity (e.g., all activities from home) and destination activity (e.g., all activities to work) are used. For the mode pattern comparison, the bike mode and the other modes with very few test data samples are eliminated. For the temporal dimension, the seasonal and the weekday-weekend variations are averaged out.

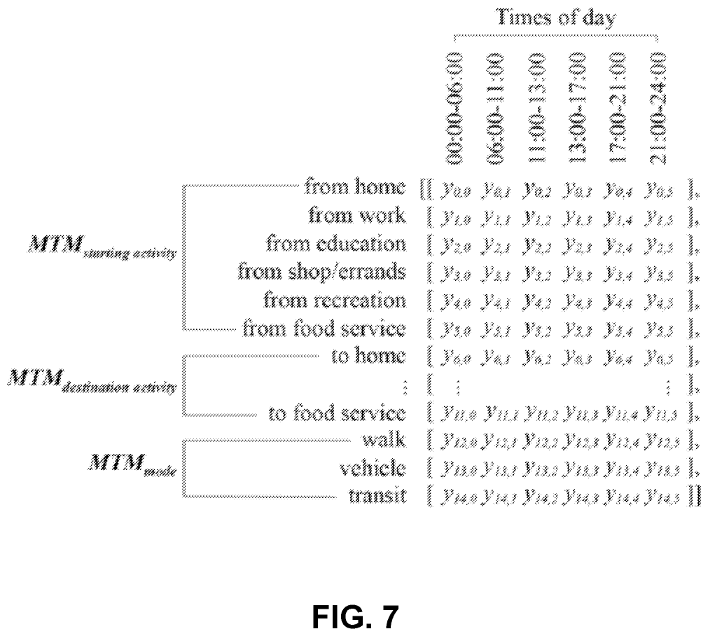

FIG. 7 shows the format of three MTMₓ for one neighborhood. These modified formats of TM, denoted as MTM_{starting activity}, MTM_{destination activity}, and MTM_{mode}, for one neighborhood, which is used for final comparison and assessment.

$${\sum }_{i = 0}^{5} {y}_{i , j} = 1 , {\sum }_{i = 6}^{11} {y}_{i , j} = 1 , {\sum }_{i = 12}^{14} {y}_{i , j} = 1 .$$

Each neighborhood's pattern estimation accuracy can be assessed by comparing its estimated pattern [symbol] and the observed pattern MTMₓ. The comparison is quantified using R² and Root Mean Square Error (RMSE) as shown in Equation (6) and Equation (7). R² represents the proportion of variance in MTMₓ that is explained by [symbol] and RMSE measures the absolute difference between the two:

$${R}^{2} ( M T {M}_{x} , \text{?} ) = 1 - \frac{\sum {( {y}_{i , j} - {\hat{y}}_{i , j} )}^{2}}{\sum {( {y}_{i , j} - \overline{y} )}^{2}} \qquad ( 6 )$$

$$RMSE ( {MTM}_{X} , \text{?} ) = \sqrt{\frac{\sum {( {y}_{i , j} - {\hat{y}}_{i , j} )}^{2}}{m}} \qquad ( 7 )$$

where m is the total number of elements (i.e., m=36 for MTM_{starting activity} and MTM_{destination activity}, 18 for MTM_{mode}), and

$$\overline{y} = \frac{1}{m} \sum {y}_{i , j} .$$

Since every neighborhood has its own R² and an RMSE value, the mean and standard deviation of all neighborhoods' R² and an RMSE can be calculated as the final statistical metric for assessing the overall accuracy. Additionally, the spatiotemporal comparison results can be visualized through plots and maps.

Based on the training results, eight representative traveler clusters, denoted C1 through C8, were identified. Various types of diagrams may be used to visualize the cluster centroids concisely and effectively. Some of these diagrams can be generated by first factoring the trip count probabilities into the other two choice probabilities respectively. One type of diagram includes activity patterns during the summer weekday, which demonstrate the estimated number of trips per traveler between pairs of starting and destination activities. Such a diagram may illustrate activity choice patterns of cluster centroids, with arrow thickness indicating number of trips per person regarding the corresponding pair of starting and destination activities.

Based on dominant activity types, C1, C4, C5, and C7 are mainly work commuters. Their trips during the morning are primarily from home to work, and their trips in other time windows are also generally work-related. C2, C6, and C8 are more involved in leisure travel, such as shopping/errands and recreation. Their most active time window is around noon instead of the morning. C3 is mainly a cluster of students who make education-related trips. All clusters produce the least number of trips during the early morning and the night, but slight variations in the travel schedule can still be detected. For example, the early-morning work-commute percentage in C4 is more noticeable than in other clusters.

Another example diagram that may be used is to present mode choice patterns of cluster centroids with the number of trips per person in different modes. In the present embodiments, it was found that while most clusters have a dominant preference for the vehicle mode, C5 and C6 demonstrate considerably more diverse mode choices. Moreover, C5 is the only cluster with a non-zero bike mode share. It is also found that there are slightly more active trips (i.e., trips taking active modes including walking and biking) on the weekend than on the weekday. Similarly, the number of active trips in the summer is marginally higher than in the winter given the same temporal and cluster context.

With regard to cluster socio-demographics, it was found that the cluster membership classifier has an average predictive accuracy of 98.6% in the cross-validation process.

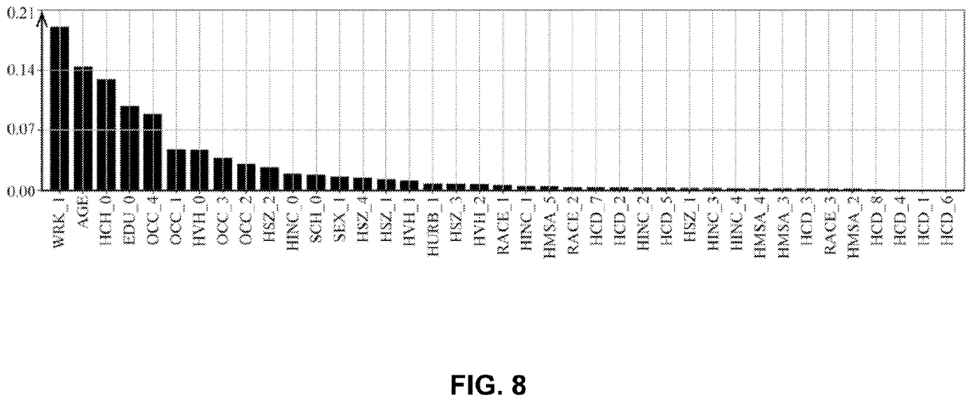

FIG. 8 is a graph of feature importance rankings for the cluster membership classifier, showing the relative importance of the socio-demographic features that determine the cluster assignment, using the feature names shown in Table 1. As is apparent from the figure, the top ten features in this embodiment are WRK_1, AGE, HCH_0, EDU_0, OCC_4, OCC_1, HVH_0, OCC_3, OCC_2 and HSZ_2, in order of decreasing importance. Note that each feature has dropped one discretized level to avoid information redundancy.

These feature rankings illustrate the importance of particular features such as age (AGE), having children (HCH), education (EDU), vehicle count (HVH), household size (HSZ), and income (HINC), at various discretized levels, in illustrative embodiments. For example, whether the household owns zero vehicles (HVH_0), has two people (HSZ_2), or is the lowest income group (HINC_0) has more influence on mobility choices than other discretized levels of these features. Additionally, the feature rankings show that the worker status (WRK_1) and different types of occupations (OCC_1, OCC_2, OCC_3, and OCC_4) are especially impactful to human mobility patterns.

Another finding is that the socio-demographic features that embody the geographic context, including the urban and suburban indicator (HURB), the household metropolitan statistical area size (HMSA), and the household census division (HCD) have median to low rank of importance. This means that different geographic contexts are not significant enough to yield separate clusters. This also points to the possibility that these geographic variations have been already captured by other socio-demographic features. For example, people with certain occupations, income levels, and household types are more likely to live in urban areas rather than in the suburbs. Thus, having these features in the model may impair the significance level of the HURB feature.

To further characterize the identified clusters, the percentages of clusters in the training dataset as well as their average SDP are demonstrated in Table 3. The most prevalent clusters are C8, C4, and C1. In contrast, the travelers who use diverse travel modes (C5 and C6) only consist of 1.1% and 2.3% of all samples from the national travel survey.

TABLE 3
Clusters characterized by socio-demographic features.

| | | Average socio-demographic features | | | | | | | | | | |
|---|---|---|---|---|---|---|---|---|---|---|---|---|
| | % | WRK_1 | AGE | HCH_0 | EDU_0 | OCC_4 | OCC_1 | HVH | OCC_3 | OCC_2 | HSZ | HINC_0 |
| C1 | 20.0 | 1.0 | 50.2 | 1.0 | 0.1 | 0.7 | 0.1 | 2.3 | 0.0 | 0.2 | 2.0 | 0.1 |
| C2 | 8.3 | 0.2 | 41.5 | 0.3 | 0.6 | 0.0 | 0.0 | 2.3 | 0.0 | 0.0 | 3.7 | 0.5 |
| C3 | 3.3 | 0.1 | 17.5 | 0.2 | 1.0 | 0.0 | 0.1 | 3.0 | 0.0 | 0.0 | 4.0 | 0.2 |
| C4 | 20.2 | 1.0 | 46.1 | 0.8 | 0.9 | 0.2 | 0.4 | 2.6 | 0.3 | 0.1 | 2.7 | 0.4 |
| C5 | 1.1 | 1.0 | 40.5 | 0.9 | 0.5 | 0.5 | 0.3 | 0.2 | 0.1 | 0.1 | 2.0 | 0.6 |
| C6 | 2.3 | 0.0 | 59.6 | 0.9 | 0.8 | 0.0 | 0.0 | 0.0 | 0.0 | 0.0 | 1.6 | 0.9 |
| C7 | 11.1 | 1.0 | 41.6 | 0.0 | 0.2 | 0.7 | 0.1 | 2.4 | 0.0 | 0.1 | 3.9 | 0.1 |
| C8 | 33.8 | 0.0 | 68.9 | 1.0 | 0.6 | 0.0 | 0.0 | 2.1 | 0.0 | 0.0 | 1.9 | 0.5 |

In Table 3, only the top-ranked socio-demographic features are analyzed. By linking Table 3 with the travel patterns of clusters, some correlations can be detected. For example, the cluster of students (C3) has the youngest average age (AGE=17.5). The clusters of leisure travel (C2, C6, C8) all have a low percentage of workers (WRK_1=0.2, 0.0, 0.0). The early-morning commuters (C4) have a relatively higher percentage of people who have no bachelor's degree (EDU_0=0.9). One of the clusters that rely on diverse mode choices including walking and transit (C6) is mainly made up of low-income households (HINC_0=0.9) with no household-owned vehicles (HVH=0.0). These findings provide insights into the various travel routines of different types of people.

Table 4 shows the statistical metrics of the accuracy assessment. The mean R² indicates that the estimation results can explain an average of 65.47%, 53.15%, and 72.04% of the variations in observed MTM_{starting activity}, MTM_{destination activity}, and MTM_{mode}. The mean RMSE value indicates that the average differences are 10.32%, 11.06%, and 12.58%. The comparatively large standard deviations of these two metrics reiterate the finding of high spatial heterogeneity of neighborhood-level accuracy.

TABLE 4
The statistical accuracy of the neighborhood-level MTMₓ estimation.

| | R² | | RMSE | |
|---|---|---|---|---|
| Analyzed pattern | mean | std. dev. | mean | std. dev. |
| starting activity | 0.6547 | 0.1391 | 0.1032 | 0.0461 |
| destination activity | 0.5315 | 0.2119 | 0.1106 | 0.0504 |
| mode | 0.7204 | 0.4769 | 0.1258 | 0.0718 |

Spatial differences in mobility patterns across neighborhoods may be further investigated by taking the daily average probabilities of each choice option (i.e., the average value of each row in [symbol] and MTMₓ) for each neighborhood and mapping them. This allows comparing of the spatial pattern regarding each choice option. Each map is scaled by its own minimum and maximum to show relative differences instead of magnitude differences, where

$${R}^{2} = 1 - \frac{\sum {( {y}_{i} - {\hat{y}}_{i} )}^{2}}{\sum {( {y}_{i} - {\overline{y}}_{i} )}^{2}}$$

where yᵢ(ŷᵢ) is the observed (estimated) value for each neighborhood i after min-max scaling, and y̅ is the mean of yᵢ across all neighborhoods. Such further investigation in illustrative embodiments found a noticeable similarity in the major mobility trends between the estimated and observed maps. However, more nuanced spatial variations among neighborhoods are not precisely estimated, which is reflected in the R² value that is used for quantifying the similarity between each pair of maps. Most of R² values are close to or smaller than 0 due to large discrepancies in certain neighborhoods.

These embodiments use a generalizable clustering approach to investigate the effects of socio-demographic features on human travel patterns at the cluster and neighborhood levels. At the cluster level, eight representative traveler clusters that can generalize travel behavior were identified, and the primary socio-demographic features that characterize these clusters were determined. At the neighborhood level, the aggregate travel choice patterns are estimated based on the cluster percentages and the cluster centroids, which is also a generalizable approach for any neighborhood. The assessment results from these embodiments suggests that the SDPs of the traveler population produce a good approximation of the average temporal mobility patterns at the aggregate level.

However, the clustering-based estimation method in some embodiments may not precisely capture the spatial differences in the mobility patterns across different neighborhoods. This could be because factors other than socio-demographics, such as physical and built environment factors, are contributing to the spatial differences but are neglected in this case study. For instance, the example estimation approach would not differentiate two neighborhoods that share the same cluster percentages but have very different spatial and environmental configurations such as terrain, street quality, or amenity densities. Other embodiments could include these environmental factors in the modeling to help enhance spatial resolution and prediction accuracy, using the example approach and results described above as a baseline or benchmark.

The example clustering approach has the unique advantage of simplicity in characterizing a population's mobility preferences. This advantage provides the opportunity to answer questions or solve problems that can otherwise be much more challenging. For instance, by tracing the cluster percentages of neighborhoods during a certain period or comparing cluster percentages before and after major urban renovations, one can get insights into the population dynamics from a mobility perspective. In activity-based travel demand modeling, this advantage can help simplify and accelerate the procedure of population synthesis, a process of synthesizing traveler population for use in agent-based trip generation. If a population needs to be synthesized using all socio-demographic features of interest (e.g., 14 features in some embodiments), a high dimensional contingency table (i.e. the complete distribution across all selected features) might otherwise need to be estimated using conventional methods like iterative proportional fitting procedure. With the clustering disclosed in these embodiments, each travel agent can be described by one single integer indicating the cluster membership, and a population can be described by a simple vector of cluster percentages. This is a significant improvement from the perspective of model simplicity and efficiency.

This example approach is mainly limited by the selection of socio-demographic features and the sample size of the NHTS data. The NHTS data is a comprehensive dataset, that provides nationwide daily travel records together with detailed personal and household information. Other popular mobility data sources, including passively generated travel data such as GPS data and social media data, fall short of collecting socio-demographic information. The reliance on the NHTS data in some embodiments leads to the problem that it can only analyze the features that are included in the NHTS data. The identified clusters could also be less representative of the areas that are not well sampled.

It should also be noted that the clustering in this example approach is conducted based on the synthesized pattern TM instead of the actual observed data. Individuals can be clustered according to their behaviors instead of superimposing any predefined socio-demographic features on the observations. However, the example approach is appropriate because it considers a large set of socio-demographic features and does not ignore temporal differences, unlike previous approaches which used pre-specified subgroups defined by a few features such as age or gender and neglected temporal variations. Moreover, the example approach in these embodiments can synthesize seasonal variations in travel patterns for nationwide travelers, which is challenging to obtain through observations because consecutive travel data is only achievable for days or weeks in a certain surveyed region but is almost infeasible to be collected for a year covering wider geographic scope.

As indicated previously, in the above embodiments, eight representative traveler clusters characterized by socio-demographic features were identified, and it was found that the weighted average of the derived cluster centroids can replicate the neighborhood-level temporal mobility choice patterns well. This finding adds to evidence that aggregate human travel patterns can be regarded as regular and therefore are predictable. It shows that socio-demographic features alone are sufficient to produce a good estimation of the average temporal mobility choice patterns of a population. However, the example clustering-based approach, although capable of capturing some major spatial variations among urban regions, has moderate to low accuracy in estimating spatial differences in mobility patterns across neighborhoods. This can be addressed in other embodiments by incorporating more comprehensive environmental factors into mobility studies to enhance spatial resolution and predictive accuracy. Overall, the example clustering-based estimation framework in the present embodiments provides generalizable and easy-to-implement proxy models for estimating aggregate human travel patterns. It can serve as a baseline and benchmark for future mobility studies that take the socio-demographics of the traveler population into consideration in modeling.

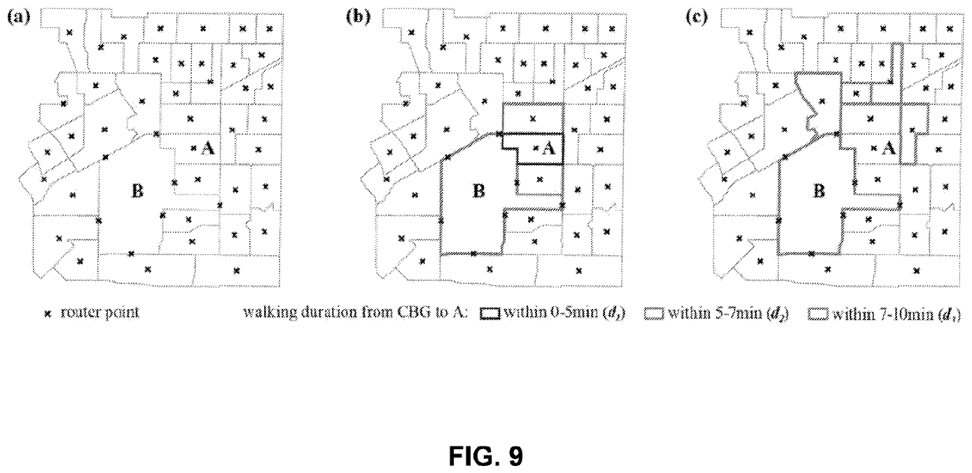

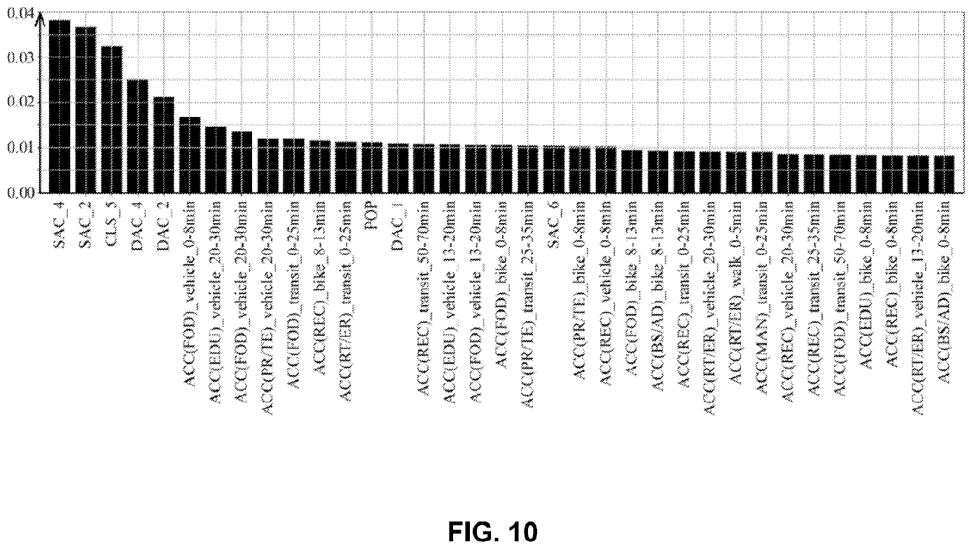

Additional illustrative embodiments will now be described with reference to FIGS. 9 and 10. These embodiments relate to assessing mobility impacts of the urban built environment, and provide a data-driven framework and case study in California. More particularly, these embodiments include a data-driven framework for predicting the impacts of the built environment on aggregate travel mode-duration choices. To parametrize the built environment, multiple accessibility (ACC) features are provided to measure the urban service densities on different scales of the transportation network. The predictive framework in these embodiments is mainly driven by a machine learning classifier that predicts mode-duration choice probabilities based on built environment features and other selected travel features. The classifier is trained through a cross-validation process that uses the L1 Norm to measure goodness-of-fit. Through a sensitivity analysis and a proof-of-concept case study, it is found that a dense, mixed-use environment with good coverage of the multi-modal mobility network can significantly promote active transportation and public transit use. It is also found that an ultra-dense centralized development could lead to an increased driving time per trip despite the decreased vehicle use percentage. This framework enables a fast and effective quantification of mobility implications of design scenarios in the early-stage decision-making process, which can potentially lead to substantial economic, environmental, and societal gains.

The global urban population is projected to grow significantly by 2050, which indicates that existing urban mobility problems like congestion and pollution could be further aggravated in the coming thirty years. The widely recognized objectives for future urban planning include reducing travel distances in cities and increasing accessibility to more sustainable urban transport solutions. For example, California Transportation Plan 2050 envisions reducing total vehicle distance traveled by up to 27 percent and supporting a shift from 13 percent to 23 percent of all trips occurring by non-auto modes such as walking, biking, and public transit. Once achieved, it can significantly mitigate congestion, protect the environment, and enhance the quality of life.

Well-informed mobility-aware decision-making in spatial planning and urban design is imperative to realizing these goals. Built environment factors, such as placement of urban services, population density allocation, and network design, have fundamental impacts on human travel behavior such as mode choice and travel distance. Although these factors are found to have modest individual impacts, typically just a few percent of total travel, they are synergistic and therefore have a significant combined effect on the transportation. Urban infrastructure and spatial patterns are much more costly to change once established than policies like parking pricing or gasoline taxing. This makes spatial planning and urban design approaches widely regarded as stable, long-term, and cost-effective ways to alleviate transportation congestion and emissions.

Despite the urgent need, integrating transportation consideration into the spatial planning and urban design process remains challenging due to the lack of tools to quantify the mobility implications of design scenarios. More specifically, there is currently no straightforward way to inform designers, during the early phase of decision-making, about the amount of mode shift that can be elicited by implementing their scenarios. There are existing state-of-the-art approaches in transportation and land use planning such as activity-based models, modified four-step models, and integrated transport-land use models. They are used for precise modeling of the network equilibrium considering detailed factors such as safety, performance, and cost. However, designing, calibrating, and implementing these highly specialized models in practice is a complex and demanding task that needs to be handled by experts. There is a need for simplified and targeted models for evaluating spatial planning and design strategies so that designers and planners can be equipped with modeling capability.

The data-driven machine learning techniques in the illustrative embodiments described below address this need. For example, illustrative embodiments can advantageously capture a more comprehensive mobility environment at larger spatial scales while being straightforward to use and interpret during the design process. These embodiments facilitate the use of important metrics, such as travel duration and/or travel distance.

More particularly, the embodiments to be described address the deficiencies of conventional practice by providing a data-driven framework, with a novel set of built environment features, for assessing impacts of the built environment on the aggregate distribution of travel mode and duration. The mode and duration choices are modeled as joint choices regarding pre-defined discretized levels. The built environment factors include a new series of ACC features that measure the total number of different jobs within different mode-duration levels from the analyzed location. A machine learning classifier is trained to predict the mode-duration probabilities of a given trip based on the ACC features of where it starts, along with other selected travel features. With this classifier, the predictive framework can be sensitive to the built environment changes such as urban densification, land-use re-allocation, and transportation network modification. As a proof-of-concept case study, the model is trained and the predictive framework is applied to LA City. A sensitivity analysis is conducted for evaluating the marginal effects of the built environment features. A case study is used to showcase the predicted mobility impacts of several hypothetical urban development scenarios. As will become apparent, these embodiments provide a predictive framework with new features and metrics that can facilitate mobility-aware decision-making in urban design and planning practices.

The travel data is sourced from the 2017 NHTS California Add-On data, which contains 81474 trip records made by 19311 unique individuals after the data cleaning. Table 5 defines the discretized levels of the mode-duration choice set. Each choice combines a mode (m) and a corresponding duration level (d), such as walking by 0-5 minutes. The mode refers to the dominant travel mode of each trip. The trip duration is self-reported by recording the start time and the end time. The duration levels are defined based on the 20%, 40%, 60%, and 80% quantile of durations of all trips by the mode in the NHTS data.

TABLE 5
Mode-duration choice set.

| | Duration Level d (minute) | | | | |
|---|---|---|---|---|---|
| Mode m | d₁ | d₂ | d₃ | d₄ | d₅ |
| | min-max (median) | | | | |
| Walk | 0-5 (5) | 5-7 (7) | 7-10 (10) | 10-15 (15) | >15 (26) |
| Bike | 0-8 (5) | 8-15 (10) | — | 15-30 (22) | >30 (45) |
| Vehicle | 0-8 (5) | 8-13 (10) | 13-20 (15) | 20-30 (30) | >30 (45) |
| Transit | 0-25 (7) | 25-35 (30) | 35-50 (45) | 50-70 (60) | >70 (95) |

In Table 5, trips in NHTS data that are taken by modes other than walking, biking, vehicle, and transit are dropped (2.5% of all trip records). The bike mode has the same 40% and 60% quantile duration (i.e., both are 15 minutes) thus it has one less duration level. Also, the duration of the transit trips are derived by subtracting the self-reported waiting time from the total travel duration.

Table 6 describes the travel-related predictor features regarding the trip and the traveler. The trips are geo-coded by specifying the Census Block Group (CBG) of the origin location. Note that the traveler is only identified by the cluster membership regarding 8 traveler clusters. These are clusters representing distinct travel patterns of individuals across the U.S.

TABLE 6
Description of travel features.

| Abbr. | Feature Name | Type | Description/Levels |
|---|---|---|---|
| | Trip Features | | |
| — | origin CBG | Numerical | the FIPS code of the CBG |
| | | | in which the trip started |
| SSN | season | Categorical | 0 = winter (December, |
| | | | January, February); |
| | | | 1 = spring (March, |
| | | | April, May); |
| | | | 2 = summer (June, July, |
| | | | August); 3 = |
| | | | fall (September, |
| | | | October, November) |
| WKD | weekend | Categorical | 0 = weekday; 1 = weekend |
| TOD | time of day | Categorical | 0 = early morning |
| | | | (12 pm-6 am); |
| | | | 1 = morning (6 am-11 am); |
| | | | 2 = noon (11 am-3 pm); |
| | | | 3 = afternoon (3 pm-5 pm); |
| | | | 4 = evening (5 pm-9 pm); |
| | | | 5 = night (9 pm-12 pm) |
| SAC | starting activity | Categorical | 0 = from other; 1 = from |
| | | | home; 2 = from work; |
| | | | 3 = from education; |
| | | | 4 = from shop/errands; |
| | | | 5 = from recreation; |
| | | | 6 = from food service |
| DAC | destination | Categorical | 0 = to other; 1 = to home; |
| | activity | | 2 = to work; |
| | | | 3 = to education; |
| | | | 4 = to shop/errands; |
| | | | 5 = to recreation; |
| | Traveler Features | | 6 = to food service |
| CLS | traveler cluster | Categorical | 1 = cluster 1; . . . ; |
| | | | 8 = cluster 8 |

In Table 6, FIPS stands for the Federal Information Processing Standard codes which uniquely identify the CBG.

The built environment features, as shown in Table 7, include the population density (POP) and a series of ACC features. The POP is sourced from the 2018 American Community Survey 5-year Estimates from the U.S. Census Bureau. The ACC features are derived from the 2018 LEHD Origin-Destination Employment Statistics (LODES), also from the U.S. Census Bureau. These features are matched to the trip features by the trip origin CBG.

TABLE 7
Description of built environment features.

| Abbr. | Feature Names | Type | Description |
|---|---|---|---|
| — | CBG | Numerical | the FIPS code of the CBG |
| POP | population | Numerical | no. residential |
| | density | | population per square |
| | | | kilometer |
| | Accessibility | | |
| ACC | Features | | |
| ACC(RT/ER) | accessible retail/ | Numerical | no. retail/errands |
| | errands service | | (RT/ER) service jobs |
| | density by | | (NAICS sector 42, |
| | mode-duration | | 44-45, 48-49, 53, |
| | levels | | 81) by mode-duration |
| | | | levels |
| ACC(REC) | accessible | Numerical | no. recreational |
| | recreational | | (REC) service jobs |
| | service ensity | | (NAICS sector 71) |
| | dby mode- | | by mode-duration |
| | duration levels | | levels. |
| ACC(FOD) | accessible food | Numerical | no. food (FOD) |
| | service density | | service jobs (NAICS |
| | by mode- | | sector 72) by mode- |
| | duration levels | | duration levels |
| ACC(BS/AD) | accessible | Numerical | no. business/ |
| | business/ | | administrative (BS/AD) |
| | administrative | | service jobs (NAICS |
| | service | | sector 56, 92) by |
| | density by | | mode-duration levels |
| | mode-duration | | |
| | levels | | |
| ACC(MAN) | accessible | Numerical | no. manufacturing |
| | manufacturing | | (MAN) service jobs |
| | service density | | (NAICS sector 11, |
| | by mode- | | 21-23, 31-33) by |
| | duration levels | | mode-duration levels |
| ACC(PR/TE) | accessible | Numerical | no. professional/technical |
| | professional/ | | (PR/TE) service jobs |
| | technical service | | (NAICS sector 51-52,54- |
| | density by | | 55, 62) by mode- |
| | mode-duration | | duration levels |
| | levels | | |
| ACC(EDU) | accessible | Numerical | no. educational (EDU) |
| | educational | | service jobs (NAICS |
| | service density | | sector 61) by |
| | by mode- | | mode-duration |
| | duration levels | | levels |

The ACC features of a CBG are derived by counting the jobs of different industries by mode-duration levels from the CBG's router point. Each ACC feature can be denoted as ACC(X)_m_d (e.g. ACC(EDU)_walk_0-5 min) where X is the abbreviation of industries as listed in Table 7. Equation (8) defines the ACC features:

$$ACC ( X ) \_m \_d = {\sum }_{{d}_{m , i} = d} {N}_{X , i} \qquad ( 8 )$$

where N_{x,i} is the number of job X within the CBG i, and d_{m,i} denotes the duration level between the analyzed CBG and the CBG i by mode m. There would be no ACC features for the longest duration level (d₅) because the number of jobs accessible within d₅ for any mode is always infinite by definition and thus would be meaningless to be included as a predictor feature.

FIG. 9 provides an example to further illustrate the routing process for deriving ACC features. This figure more particularly includes three distinct parts, denoted (a), (b) and (c). Part (a) shows CBG router points for a particular region, and parts (b) and (c) show accessible CBGs within different walking duration levels d₁, d₂ and d₃ from a relatively small CBG, denoted as CBG A. A relatively large CBG is denoted as CBG B.

As shown in part (a) of FIG. 9, a given relatively small CBG such as CBG A (e.g., area <1 square kilometer) uses its geometric center as a single router point, while a given relatively large CBG such as CBGB (e.g., area ≥1 square kilometer) uses multiple equal-spaced points (e.g., with an interval of 900 meters) on its boundary as the router points. Parts (b) and (c) of FIG. 9 highlight the accessible CBGs within different walking duration levels from CBG A, with part (b) showing the accessible CBGs for d₁ (within 0-5 min) with one border, indicating just CBG A, and d₂ (within 5-7 min) with another border, and part (c) showing d₃ (within 7-10 min) with one border. It should be noted that CBG B falls within the different borders for both d₂ and d₃ due to its multiple router points.

In some embodiments, a software program written in C# or another suitable programming language is illustratively used for deriving ACC features for any given location across U.S. An example of the software program illustratively implements a process for deriving ACC features for a given CBG, in accordance with the example algorithm shown below.

Example Algorithm: Process of deriving
ACC features for a given CBG b₁.

```
Input: B = [b₁, b₂, ... , bₙ] (all n CBGs within the modeled region,
including the analyzed CBG b₁ itself)
Output: A dictionary ACC for b₁
foreach bᵢ ∈ B do
  foreach m ∈ [walk, bike, vehicle, transit] do
    conduct routing from b₁ to bᵢ by the mode m;
    d ← calculated duration level based on the routing result;
    foreach x ∈ all industry types do
      ACC[(x, m, d)]+= number of jobs of industry x within bᵢ;
    end for
  end for
end for
```

The routing process is illustratively conducted using Itinero, an open-source routing package based on .NET framework. The walking, biking, and vehicle trips are illustratively routed based on the street network, sourced from OpenStreetMap (OSM), with pre-defined mode-specific travel speeds. The transit routing in some embodiments is based on a separate transit network including lines and stops of subways and buses sourced from TransitFeeds. The transit routing allows switching between different lines and accounts for the walking time towards, from, and between different stops.

The modeling and analysis framework in these embodiments will now be further described, including a mode-duration choice model. For any given trip with travel features and built environment features, a choice model is trained to predict its mode-duration choice probabilities denoted as MD in Equation (9):

$$MD = [ {p}_{{m}_{1} , {d}_{1}} , … , {p}_{{m}_{i} , {d}_{j}} ] \qquad ( 9 )$$

where pₘ_{ᵢ}_{,d}_{ⱼ} is the probability of choosing mode m; and duration level dⱼ (Σpₘ_{ᵢ}_{,d}_{ⱼ}=1).

Theoretically, any form of choice model that can output the probability is applicable in this step. These embodiments use machine learning classification models due to their high generalizability, high predictive accuracy, and simple set up. Before the training, each numerical feature is scaled into the range of zero to one, and each categorical feature is one-hot encoded (i.e., encoded into multiple zero-one features regarding all discretized levels). This process yields 141 final predictor features for the choice model.

The classification model is trained through a five-fold cross-validation process during which the dataset is split into a different set of 80% training and 20% testing in each of the five iterations. The aggregate-level goodness-of-fit is measured by L1 Norm as defined in Equation (10):

$$L 1 Norm = {\sum }_{m , d} \vert {\overline{p}}_{m , d} - {\hat{p}}_{m , d} \vert \qquad ( 10 )$$

where p̅_{m,d} is the average predicted probability of the choice m and d for each data sample, and \hat{p}_{m,d} is the actual observed percentage of the choice in the dataset. A lower L1 Norm indicates a higher accuracy in predicting the aggregate distribution of choices. Multiple classification algorithms, including Random Forest, AdaBoost, Naïve Bayes, Neural Network, and K-Nearest Neighbor, are tested to select the choice model with the best predictive performance.

A sensitivity analysis examines the marginal effect of built environment features on the predicted MD by holding all other features as constants while only changing POP and ACC. Table 8 shows the feature combinations designed for this analysis. Each possible feature combination yields a separate MD result. As for the traveler cluster (CLS), the predictions are conducted separately for each cluster and then combined into a weighted average result, weighted by the cluster percentage in the entire training data. The results may be plotted, analyzed, and compared through graphs.

TABLE 8
Feature combinations for sensitivity analysis.

| | | | | | | |
|---|---|---|---|---|---|---|
| SSN | WKD | TOD | SAC | DAC | POP | All ACC Features |

| | | | | | |
|---|---|---|---|---|---|
| summer | weekday | morning | from home | to work | change from 10% quantile |
| | | | | to shop/errands | to 90% quantile in the training data |

| | |
|---|---|
| | to recreation |
| | to food service |
| from work | to work |
| | to shop/errands |
| | to recreation |
| | to food service |

Spatial scenario testing is performed as follows. With the individual-level MD per trip predicted by the choice model, the aggregate CBG-level MD per trip, denoted as [symbol] , can be calculated as in Equation (11):

$$\text{?} = {\sum }_{k} M {D}_{k} \cdot {C}_{k} \qquad ( 11 )$$

where MDₖ refers to the predicted MD regarding the traveler cluster k, and Cₖ is the percentage of cluster k in the total population of the CBG. The data source and the generalizable derivation method of Cₖ for any CBG in the U.S. are introduced in the Traveler Cluster section of the Supplementary Material. The derived [symbol] takes the same format as of MD from Equation (9) where each element can be denoted as \tilde{p}ₘ_{ᵢ}_{,d}_{ⱼ}.

To quantitatively evaluate the mobility environment of a CBG, two metrics are derived from [symbol] . The first metric is the mode percentage per trip, denoted as Mₘ in Equation (12):

$${M}_{m} = {\sum }_{j} {\tilde{p}}_{m , {d}_{j}} \qquad ( 12 )$$

The second metric is the estimated travel time per trip by mode m, denoted as Dₘ in Equation (13):

$${D}_{m} = {\sum }_{j} E [ {d}_{j} ] \times {\tilde{p}}_{m , {d}_{j}} \qquad ( 13 )$$

where E[dⱼ] refers to the expectation of travel duration of the level dⱼ regarding the mode m. In some embodiments, the median durations in Table 5 are used as the E[dⱼ]. As indicated previously, a case study was conducted in LA City. It evaluates the current mobility environment and predicts the mobility impacts of several hypothetical urban development scenarios using the metrics of Mₘ and Dₘ in the urban context of LA City. Table 9 defines the three hypothetical scenarios to be tested. Scenario 1 and Scenario 2 densify the built environment by increasing the job counts within a neighborhood. Scenario 3 modifies the network by adding a new rail line. The type of trips that are analyzed in the case study are the commute trips (i.e., trips from home to work) in the morning of summer weekdays.

TABLE 9
Definition of hypothetical scenarios.

| | No. jobs of each CBG within the densified neighborhood | | | | | | | |
|---|---|---|---|---|---|---|---|---|
| | RT/ER | REC | FOD | BS/AD | MAN | PR/TE | EDU | Add rail line |
| Current (mean) | 89.6 | 14.7 | 35.6 | 23.1 | 42.4 | 137.5 | 24.3 | no |
| Scenario 1 | 334 | 38 | 157 | 85 | 103 | 378 | 102 | no |
| Scenario 2 | 2457 | 322 | 826 | 1141 | 1351 | 3387 | 688 | no |
| Scenario 3 | 2457 | 322 | 826 | 1141 | 1351 | 3387 | 688 | yes |

In Table 9, Scenario 1 assumes the job counts in each densified CBG are equal to the 90% quantile of all CBGs in LA City. Scenario 2 and Scenario 3 assume the 99% quantile.

The results will now be described in further detail. With regard to the choice model training results, the average L1 Norms in the cross-validation process for training the mode-duration choice model are shown in Table 10. The Random Forest classification algorithm is found to have the best predictive performance with the lowest L1 Norm of 0.1007.

TABLE 10
Average L1 Norms in the five-fold cross-validation.

| | Random | | Naive | Neural | K-Nearest |
|---|---|---|---|---|---|
| | Forest | AdaBoost | Bayes | Network | Neighbor |
| Average L1 | 0.1007 | 1.0495 | 0.3034 | 0.1071 | 0.1244 |
| Norm | | | | | |

The feature importance rank of the final Random Forest classifier is used to reveal the most important features that determine the mode-duration choice of a trip.

FIG. 10 shows the top 35 features (i.e., the most significant 35 features out of the total 141 predictor features) in the feature importance rank of the mode-duration choice model. Feature names are represented by the abbreviations and the discretized levels as shown in Table 6 and Table 7.

It is first found that travel activity has a significant impact on the mode-duration choice. More specifically, whether a trip starts from or goes to shop/errands or work (SAC_4, SAC_2, DAC_4, and DAC_2) ranks highest. This finding emphasizes the importance of considering human activity in mobility studies. Further, it is found that none of the time features (i.e., season, weekday, time of day) are in the top 35 ranking. This indicates that, given the activity, traveler, and built environment, the mode-duration decision-making is not significantly influenced by time. However, note that the activity features may have already a time context embedded. For instance, trips from home to work may happen mostly in the morning and on weekdays.

For ACC features, it was found that the accessibilities for vehicle and transit duration levels are the most impactful while the ones measured by walking duration levels are the least significant. This implies the need to consider a larger contextual built environment (e.g., no less than a 30-minute driving distance from the analyzed location) in the choice modeling rather than only measuring the nearby environment (e.g., within a walkable distance of 1.5 kilometer or within one CBG). Another finding is that the ACC of food services (ACC(FOD)) appears as the most highly ranked, which implies the importance of foodservice distribution in shaping the daily travel pattern of urban residents.

With regard to the sensitivity analysis results, the predicted MD based on all feature combinations in the sensitivity analysis were determined, including how the modal split (Mₘ) changes as the built environment features (POP and ACC) increase. It was found that the mode percentages do not change significantly until the POP and ACC features reach around 50% quantile of the data. It was also found that the built environment does not have much mobility impact until it reaches a certain density. Another finding is that the magnitude of changes in modal split varies by mode. The most significant increase is in the walking mode which is near 13%, followed by the increase in the transit mode which is near 5%. The increase in the biking mode is the most subtle which is less than 1%. Moreover, the biking mode follows a different pattern as POP and ACC increase. The bike use stops growing and even starts decreasing given the higher POP and ACC inputs. One possible explanation is that the increase in biking trips is overtaken by walking and transit use.

In addition, some distinct changing patterns regarding the travel durations can be detected. The main and unexpected finding is that, for the vehicle mode, although the short-duration trips are significantly replaced by alternative modes, the long-duration trips (e.g., trips of d₅) show an opposite trend which is increasing when the environment is densified. This is potentially due to the impacts of the congestion. In other words, it is likely that the same distance or even shorter trips can take more time in the dense urban areas with congestions, leading to an increased probability of long-duration driving trips.

With regard to spatial scenario testing results in the case study, spatial distributions of the CBG-level mode percentages (Mₘ) were determined. In the example LA City environment, which includes West, Central and Valley regions, the West and Central regions are overall more walkable and less reliant on vehicles due to their overall high level of density and accessibility. The Central region also produces the most percentage of transit trips since it has the best accessibility to the transit network. For the biking mode, the West region has a slightly more percentage of biking trips, but the overall spatial heterogeneity is less noticeable than in other modes. Regarding the three scenarios, all of them are predicted to be able to decrease the use of private vehicles and encourage the alternative modes in the Valley region to different extents.

To further assess the mobility impacts, the differences in mode percentages (denoted as ΔMₘ) are computed before and after implementing the scenarios. Contrary to the mainly influenced areas in the Valley region, some opposite patterns of change are detected in the Central region, such as decreased walking percentage, decreased biking percentage, and increased vehicle use percentage, especially in Scenario 2 and Scenario 3. This finding provides evidence that built environment changes in one neighborhood could have mobility impacts reaching far beyond its nearby areas. It also shows that urban densification is not always beneficial to all areas in the city if the density is not well-distributed but rather centralized in a single area. The potential reason for the opposite patterns of change could be that the densified areas form new attractions that elicit new demands for vehicle trips starting from distant neighborhoods and coming to these new places. For the biking mode, there are reduced biking percentages within the Valley region as well. This could be due to the biking mode being overtaken by the increased walking and transit mode in these areas.

Differences of the CBG-level mode percentages (ΔMₘ) in the three hypothetical scenarios were also determined. Analysis similar to that described previously is done for the CBG-level estimated travel time per trip (Dₘ) and their differences (denoted as ΔDₘ). It is observed that, for the walking, biking, and transit mode, the overall changing patterns are similar to the findings of Mₘ and ΔMₘ. However, a different phenomenon was found for the vehicle travel mode. More particularly, only those CBG within and near the densified neighborhood have decreased Dₘ. The areas surrounding the densified neighborhood all have longer Dₘ even though some of them have reduced vehicle use percentages. This relates to the increased long-duration trip percentage as discussed in the sensitivity analysis above, which drives up the travel time estimation by vehicle. The most probable interpretation of this phenomenon is that these surrounding areas, with a limited number of nearby destinations, cannot sufficiently replace short driving trips and are meanwhile suffering from slower travel in all mid-to-long duration trips to the dense center area possibly due to congestion.

Table 11 summarizes ΔMₘ and ΔDₘ of all CBGs that are influenced by the scenarios (i.e., all CBGs with non-zero ΔMₘ). In Scenario 3, the maximum increase in walking percentage is up to 22.47% and the maximum reduction in vehicle use percentage is 25.88%. The maximum changes in the estimated travel time are also more than 3 minutes per trip for walking, vehicle, and transit mode. Since the case study only analyzes the commute trips from home to work during the morning period from 6 am to 11 am, these quantified changes can be significant if extrapolated to all trips of the local population and to a time span of an entire day or year. However, it is worth noting that in Scenario 2 and Scenario 3, although the use of private vehicles has been reduced drastically in certain CBG according to the minimum ΔDₘ, the mean ΔDₘ for the vehicle mode is increasing due to the trade-offs in the surrounding areas.

TABLE 11
Average and maximum ΔMₘ and ΔDₘ of all
CBGs that are influenced by the scenarios.

| | | Walk | | Bike | | Vehicle | | Transit | |
|---|---|---|---|---|---|---|---|---|---|
| | | mean | max | mean | max | mean | min | mean | max |
| ΔMₘ | Scenario 1 | +0.31 | +5.59 | +0.02 | +0.91 | −0.38 | −6.22 | +0.04 | +0.75 |
| (%) | Scenario 2 | +1.52 | +21.09 | −0.05 | +1.20 | −1.88 | −23.90 | +0.41 | +3.33 |
| | Scenario 3 | +1.50 | +22.47 | −0.05 | +1.20 | −1.89 | −25.88 | +0.45 | +4.66 |
| ΔDₘ | Scenario 1 | +0.04 | +0.68 | +0.004 | +0.14 | −0.05 | −1.60 | +0.02 | +0.27 |
| (minute) | Scenario 2 | +0.22 | +3.19 | −0.009 | +0.26 | +0.22 | −3.59 | +0.20 | +2.23 |
| | Scenario 3 | +0.22 | +3.19 | −0.009 | +0.26 | +0.15 | −3.43 | +0.22 | +3.34 |

These illustrative embodiments provide a predictive framework for quantifying mobility impacts of urban design interventions such as changing urban forms, densities, land uses, or networks. The framework illustratively includes a pre-trained choice model and can utilize the previously-described example software program to automatically derive or update the predictor features. The case study shows an example of such an implementation. The results and findings have several implications for practical applications. For example, the training results reveal the importance of incorporating human factors, such as activity (SAC and DAC) and socio-demographics (CLS), into the mobility modeling. As another example, the predictive results facilitate a deeper understanding of accessibility-oriented development and reiterate the importance of the mixed-use neighborhood. The example model rewards a higher level of accessibility to different goods, services, and employment opportunities. Contrarily, neither increasing the POP feature alone nor increasing the ACC features of any single industry could notably change the prediction outcome. Moreover, the case study shows that urban density is a complex factor to consider which comes with both benefits and trade-offs. These embodiments provide an example approach to quantitatively define, measure, and analyze the “optimal density.” For example, predicting ΔMₘ and ΔDₘ can support and advance this concept by quantifying the benefits and drawbacks of density and use mix configurations in cities.

Methodologically, this example framework introduces a novel set of ACC features that are comprehensive yet straightforward to use in parametrizing the density distribution of urban services on different scales of the transportation network. Various types of design modifications in the built environment can be easily converted into changes in ACC features. For example, network changes such as adding new transit lines can increase ACC of transit in nearby neighborhoods. Program allocations such as new commercial districts can lead to changes in ACC regarding retail, shopping, or food services in all neighborhoods accessible to this new development. Further, the ACC features allow the predictive framework to capture the mobility impacts not only within the newly developed zone but also in large surrounding areas. This would generally not be feasible using features that only describe densities or accessibilities within the walkable distance.

Another contribution of this framework is to model the travel mode-duration as a joint choice and solve it using a machine learning classifier. This approach significantly simplifies the predictive architecture and brings ease in evaluating mobility metrics. Not only the modal split can be directly computed from the choice probabilities, but also the travel time by mode can be properly approximated by taking expectations for each duration level. The latter metric is normally challenging to compute and requires more complex simulation approaches. Illustrative embodiments facilitate its determination, in the manner disclosed herein. Unlike trip distance in the travel survey data, which is usually post-processed based on the shortest path between the origin and the destination regardless of travel mode, illustrative embodiments use duration as a more reliable measurement of trip length, especially for modes like public transit that are prone to significant deviations from the shortest path.

This example approach is limited in some embodiments by the potential urban mobility factors that are not captured by the POP and ACC features, such as microclimate, green space, and transit schedules. These factors can be transformed into new features and added to the training data. They can also be factored into the existing ACC features. For example, parks and green spaces can be used to adjust the number of jobs in the recreational industry (REC) to better capture leisure activity densities. The case study is also limited by the survey region, precision level, frequency, and timing of the NHTS data. The trained choice model is generated for a particular region (e.g., California in this case) where the survey data was collected. The spatial resolution of the analysis (e.g., CBG) is constrained by the precision level of the reported trip locations. The potential behavioral changes in the population, such as declined transit ridership caused by the COVID-19 pandemic, can only be captured and analyzed if new survey data is collected every few years. However, the NHTS data is the only data that provides comprehensive daily travel data nationwide and therefore is a good data source that allows others to reproduce models for their regions of interest. Other popular data sources, including passively generated travel data from GPS or social media, can, in theory, be used to replace or augment the NHTS but often fall short of collecting crucial information such as socio-demographics, activity, and mode.

As described above, these embodiments provide a data-driven framework for predicting the aggregate mode-duration choices based on the urban built environment. This framework is mainly characterized by its simplicity and generalizability. The prediction is purely driven by a Random Forest classifier. The built environment is parametrized by ACC features whose derivation process can be automated using the previously-described example software program. The data-driven nature allows the framework to be deployable to any city around the globe provided that the local data is available for deriving all required predictor features. Overall, the example framework facilitates a fast and effective assessment of mobility implications of design scenarios in the early-stage decision-making process. The enabled co-design of the built environment and mobility solutions can potentially lead to substantial economic, environmental, and societal gains.

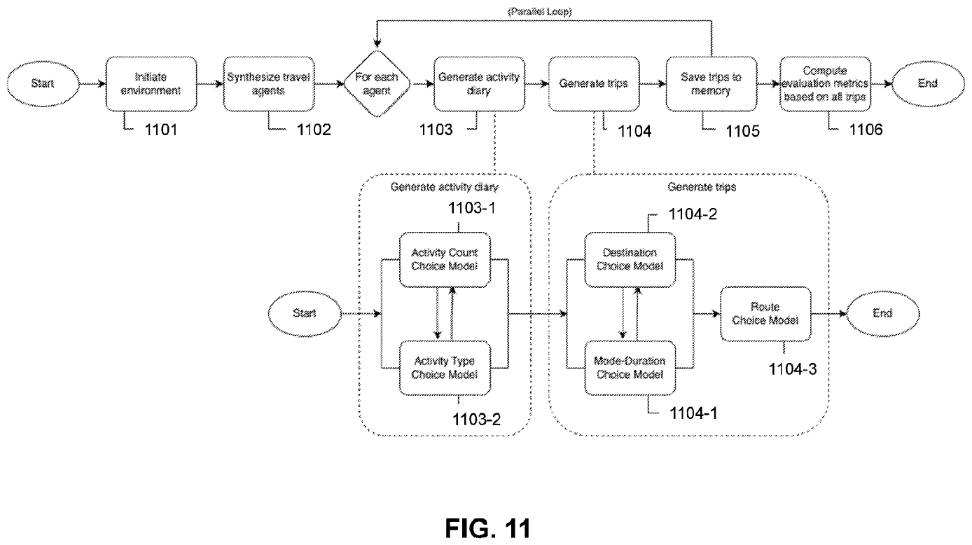

Still further illustrative embodiments will now be described with reference to FIGS. 11 through 14. These embodiments provide a data-driven agent-based mobility simulation and analysis framework, which can simulate one-day travel behaviors for a synthetic population in any user-defined urban area. The framework illustratively comprises six submodels interconnected through a Markov Chain generation process, including a traveler classifier model, an activity count choice model, an activity type choice model, a mode-duration choice model, a destination choice model, and a route choice model, although other types and arrangements of models can be used in other embodiments. These example submodels are configured to incorporate a wide range of demographic characteristics and built environment data within a given simulation. In addition to the example modeling architecture of these embodiments, several supplementary techniques are disclosed herein to further augment the computational efficiency and flexibility. These techniques include, for example, clustering-based population synthesis, adjustable spatial units, and the utilization of buffer zones.

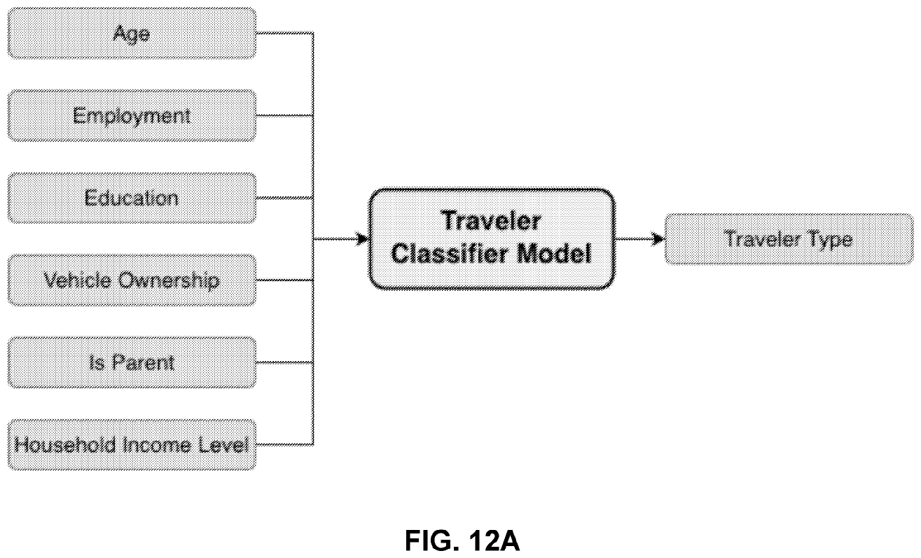

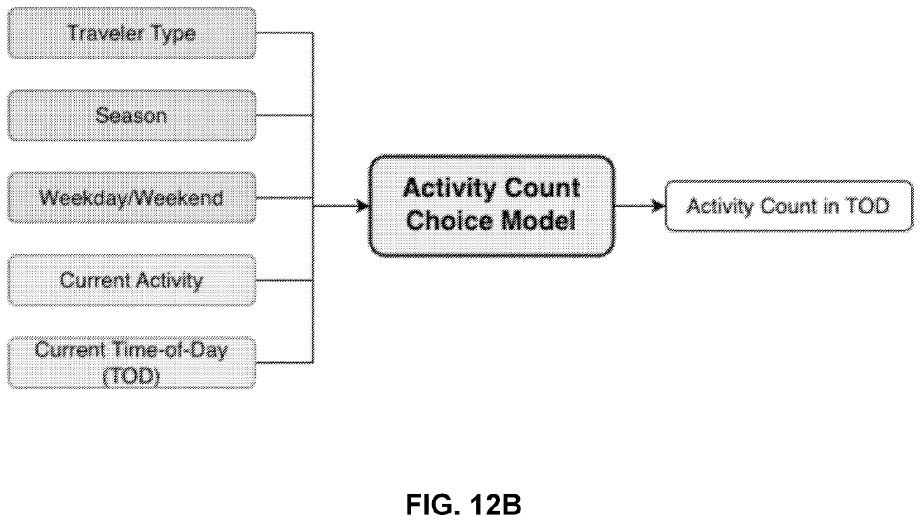

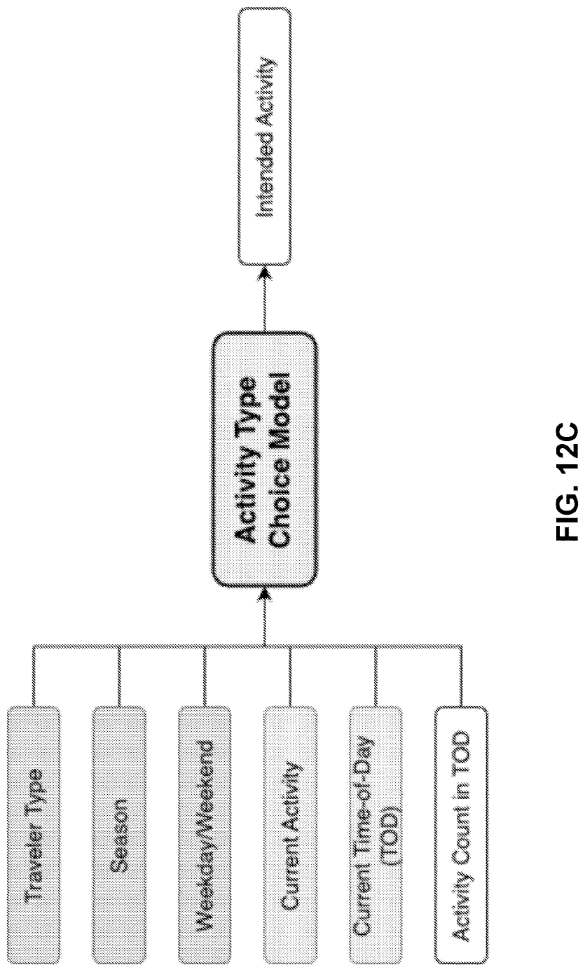

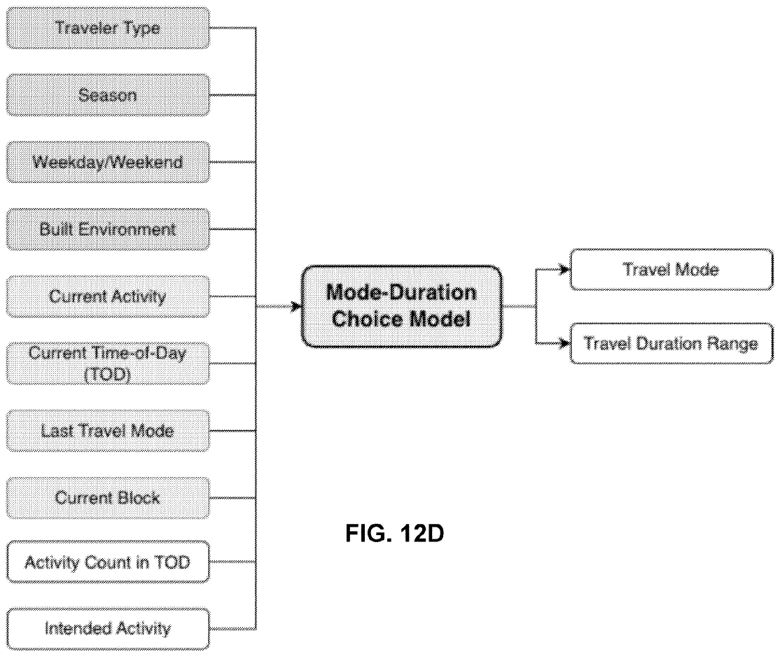

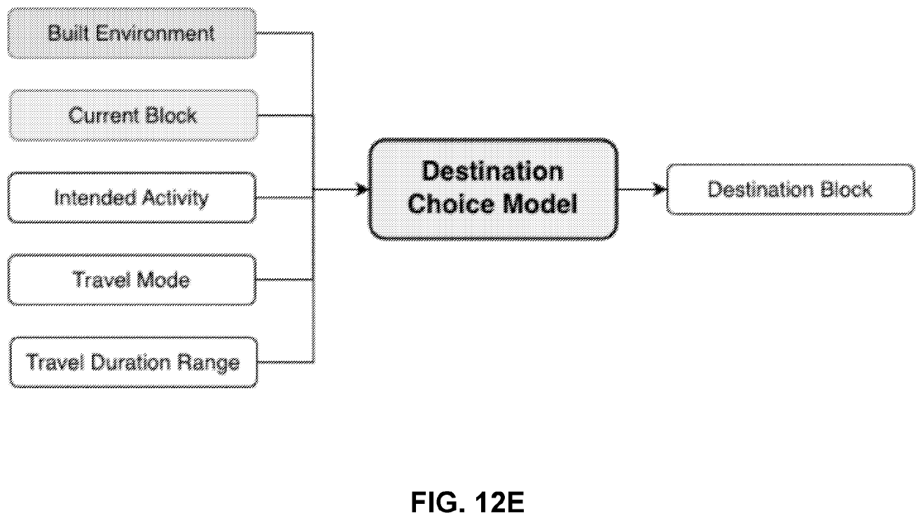

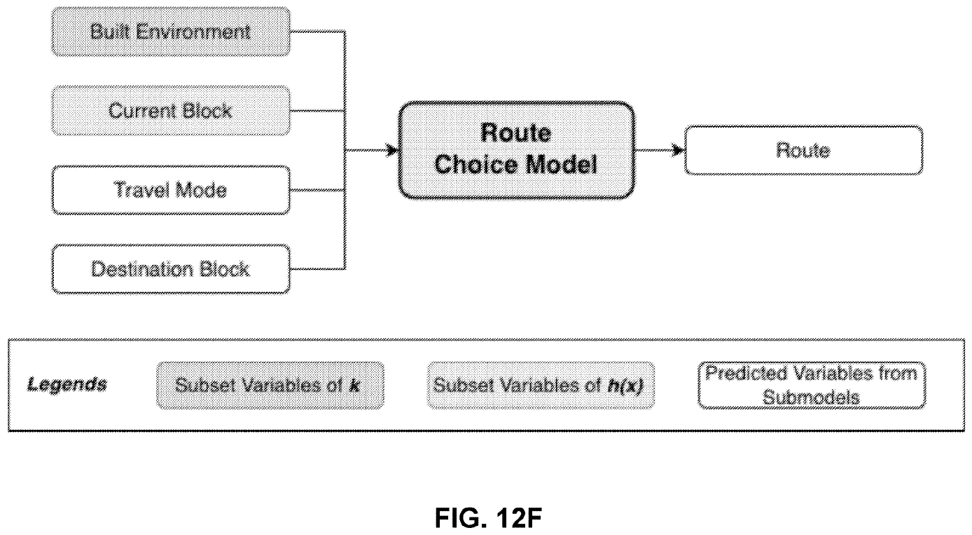

FIG. 11 illustrates the overall simulation process, and FIGS. 12A through 12F illustrate input and output data of respective ones of the six submodels. Each of the submodels is also individually referred to as a “model” herein.

The overall model in these embodiments comprises four basic entities: travel agents, blocks, roads and transit routes, each defined by a set of variables. Travel agents are distinguished by their traveler type, with each type representing a cluster of demographics that share a specific daily activity pattern and mode preference.

Blocks, roads, and transit routes represent the built environment that shapes the movement of travel agents. Blocks are where trips start or end, establishing the spatial granularity of the simulation. Each block is characterized by its residential population, tourist population, entry point for road access, green space area, number of jobs across diverse industries, and number of Points of Interest (POIs) representing various activities. The population figures determine the number of travel agents who recognize the block as their home location. The presence of green space, job opportunities, and POIs collectively influences the block's attractiveness for different activities.

Roads are categorized by their road type, which determines the accessibility level and assumed travel speeds for walking, biking, and vehicular modes. Accessibility is binary, but whether a road is favored by a particular mode can be specified by considering varied speed assumptions. For instance, a cycleway assumes a higher biking speed compared to primary vehicle roads, rendering it a preferred choice for biking within the routing algorithm that selects the fastest route. Table 12 outlines the detailed assumptions regarding the speed and accessibility of different modes on various types of roads.

Transit routes, while similar to roads, are separate networks that are exclusively accessible for the public transit mode. They are categorized by transit types such as subway lines, bus lines, and others, each with its own distinct speed assumptions. Transit routes also specify transit stops, which limits where trips can start and end on the route. To enable route transitions, like transferring between subway lines or switching from a bus to the subway, the connections between transit stops are also modeled. These connections are represented as straight lines linking all pairs of transit stops located within a particular distance (e.g., 800 meters) of each other. The assumed speed on these connections is equivalent to walking speed.

A single simulation run can generate trips for an entire day. The temporal resolution is time-of-day, including early morning (T1), morning (T2), noon (T3), afternoon (T4), evening (T5), and night (T6). The model also accounts for other temporal factors, including the season and whether it is a weekday or weekend.

TABLE 12
Speed assumptions on roads and transit routes (km/h).

| Road/Route Type | Pedestrian | Biker | Vehicle | Public Transit |
|---|---|---|---|---|
| Motorway | — | — | 60 | — |
| Primary | 4 | 12 | 40 | — |
| Secondary | 4 | 12 | 40 | — |
| Tertiary | 4 | 13.5 | 40 | — |
| Residential | 4 | 15 | 30 | — |
| Footway | 4 | 16.5 | — | — |
| Cycloway | 4 | 18 | — | — |
| Steps | 2 | — | — | — |
| subway line | — | — | — | 40 |
| bus line | — | — | — | 15 |
| links between | — | — | — | 4 |
| transit stops | | | | |

Table 12 presents default assumptions for an illustrative embodiment. Users have the flexibility to override these assumptions.

As shown in FIG. 11, the process begins with the initialization of the simulation environment (step 1101) and the synthesis of travel agents (step 1102). Each agent proceeds to establish their daily activity schedule (step 1103), followed by the generation of trips to fulfill these activities (step 1104). Subsequently, the generated trips from all agents are aggregated to compute various analytical metrics (step 1105-1106), such as block check-ins, transit stop check-ins, and road throughput. The model yields both aggregate metrics and the complete raw trip data as output.

The activity diary can be formalized as a sequence of activities s=(s₁, s₂, . . . ) with each activity sᵢ decomposed as sᵢ=(aᵢ, tᵢ), where aᵢ is the activity type, and tᵢ is the time-of-day that the activity happens. Activity type options include home, work, school, shop/errands, recreation, meal, and other. In the present embodiment, the diary always starts at the home location, meaning s₁=(home, T1). In addition, a vector c=(c₁, c₂, c₃, c₄, c₅, c₆) is defined, where cᵢ is the total count of activities within each time-of-day. This vector will help regulate the total number of activities generated.

Each activity sᵢ yields one trip. These generated trips can be formalized as g=(g₁, g₂, . . . ) with each trip gᵢ decomposed as gᵢ=(mᵢ, dᵢ, bᵢ, rᵢ), where mᵢ is the transport mode, dᵢ is the travel duration range, bᵢ is the destination block, and rᵢ is the route path.

FIG. 11 also illustrates the detailed process within step 1103 and step 1104 which utilizes five of the six submodels mentioned above. The activity diary s is generated through two submodels, namely, the activity count choice model and the activity type choice model. The activity count choice model generates cᵢ in sequence (step 1103-1). The activity type choice model generates each activity type aᵢ in sequence (step 1103-2). The generation of each trip gᵢ begins by predicting mᵢ and dᵢ using the trip mode-duration choice model (step 1104-1). Next, a destination block bᵢ that matches the mode-duration travel criteria is selected through the destination choice model (step 1104-2). Then, the agent is relocated to the destination block and the process starts predicting mᵢ₊₁ and dᵢ₊₁ for the next trip in the sequence. This iterative process continues until all scheduled trips are fulfilled with their destination blocks. After that, all trip routes are computed by the route choice model (step 1104-3).

The generative task illustrated in FIG. 11 can be formalized as a task of sampling x from the conditional distribution p(x|k), where x=(x₁, x₂, . . . ) with xᵢ denoting the combined data of each trip including (cₜ_{ᵢ}, aᵢ, mᵢ, dᵢ, bᵢ, rᵢ), and k represents any prior knowledge such as the socio-demography of the analyzed agent, the built environment, and the temporal context like season and weekday. This conditional distribution can be factorized as shown in Equation (14):

$$p ( x \vert k ) = p ( {x}_{1} , {x}_{2} , {x}_{3} , … \vert k ) = p ( {x}_{1} \vert k ) \cdot p ( {x}_{2} \vert {x}_{1} , k ) \cdot p ( {x}_{3} \vert {x}_{1} , {x}_{2} , k ) \cdot … , \qquad ( 14 )$$

which means the i-th trip data is generated using the transition probability p(xᵢ|xᵢ₋₁, k) with xᵢ₋₁ being all the history trip data.

To make this example model computationally feasible, the transition probability is typically reduced to p(xᵢ|h(xᵢ₋₁), k), where h(xᵢ₋₁) is a function of only a subset of xᵢ₋₁. In this example model, a Markov Chain approach is adopted and a simplified h(xᵢ) is defined that only considers (aᵢ, tᵢ, mᵢ, bᵢ) of the previous trip. The transition probability can be further represented and factorized as shown in Equation (15):

$$p ( x \vert h ( {x}^{′} ) , k ) = p ( c , a , m , d , b , r \vert h ( {x}^{′} ) , k ) = p ( c \vert h ( {x}^{′} ) , k ) \cdot p ( a \vert c , h ( {x}^{′} ) , k ) \cdot p ( m , d \vert c , a , h ( {x}^{′} ) , k ) \cdot p ( b \vert c , a , m , d , h ( {x}^{′} ) , k ) \cdot p ( r \vert c , a , m , d , b , h ( {x}^{′} ) , k ) \qquad ( 15 )$$

where subscripts are omitted for better readability and the prime symbol denotes data of the previous trip. This factorization allows decomposing the problem into smaller modules and solving them with separate machine learning models.

The five factorized terms in Equation (15) respectively correspond to the steps 1103-1, 1103-2, 1104-1, 1104-2, and 1104-3. To further simplify the simulation architecture, each submodel is designed to only take a subset of h(xᵢ) and k, and some dependences among the choices are removed. These specific configurations of the submodels are detailed in the following description.

FIGS. 12A through 12F illustrate the input and output data of the six example submodels, illustrating their interconnected choice dependencies and the distinct subsets of h(xᵢ) and k utilized by each one. A comprehensive description of these data is provided in Table 13. Note that the built environment data varies according to the submodel's formulation. For example, in the trip mode-duration choice model, specific built environment variables are calculated to be used as numerical predictor features. In contrast, for the destination choice model and the route choice model, built environment data refers to the collective representation of blocks and roads used for sampling and routing purposes.

TABLE 13
Description of data.

| Name | Type | Description/Discrete Levels |
|---|---|---|
| Prior Knowledge k | | |
| Traveler type | Categorical | cluster 1, 2, 3, 4, 5, 6, 7, 8 |
| Season | Categorical | winter (December, January, |
| | | February), spring |
| | | (March, April, May), |
| | | (June, July, August), fall |
| | | (September, October, |
| | | November) |
| Weekday/weekend | Categorical | weekday, weekend |
| Built environment | N/A | Blocks, roads, and transit |
| | | routes data |
| Trip History Data h(x) | | |
| Current activity | Categorical | home (A1), work (A2), |
| | | school (A3), shop/errands |
| | | (A4), recreation (A5), |
| | | meal (A6), other (A7) |
| Current time-of-day | Categorical | early morning 12 pm-6 am |
| | | (T1), morning 6 am- |
| | | 11 am (T2), noon 11 am-3 pm |
| | | (T3), afternoon 3 pm- |
| | | 5 pm (T4), evening 5 |
| | | pm-9 pm (T5), night 9 pm- |
| | | 12 pm (T6) |
| Last travel mode | Categorical | walk, bike, vehicle, |
| | | public transit |
| Current block | N/A | Block data |
| Predicted Data | | |
| Activity count | Categorical | 0, 1, 2, 3, 4, 5, 6 |
| in time-of-day | | |
| Intended activity | Categorical | Same as “Current activity” |
| | | variable |
| Travel mode- | Categorical | 0-5 min walk, 5-7 min |
| duration range | | walk, 7-10 min walk, 10- |
| | | 15 min walk, 15-60 min walk, |
| | | 0-8 min bike, 8-13 min |
| | | bike, 13-20 min bike, 20-30 |
| | | min bike, 30-70 min bike, |
| | | 0-8 min vehicle, 8-13 min |
| | | vehicle, 13-20 min vehicle, |
| | | 20-30 min vehicle, 30-115 |
| | | min vehicle, 0-25 min |
| | | transit, 25-35 min transit, |
| | | 35-50 min transit, 50-70 min |
| | | transit, 70-143 min transit |
| Destination block | N/A | Block data |
| Route | N/A | Route path data |

Built Environment Variables for
Trip Mode-Duration Choice Model (N = 61)

| | | |
|---|---|---|
| Population density | Numerical | Residential population |
| | | per square meter within |
| | | 500 m radius |
| Shop/errands- | Numerical | Number of shop/errands jobs |
| related job | | (NAICS sector 42, 44-45, 48-49, |
| distributions | | 53, 81) within 5 min, 5-10 min, |
| | | 10-15 min walking, 8 min, 8-15 |
| | | min biking, 25 min public |
| | | transit |
| Recreation-related job | Numerical | NAICS sector 71 |
| distributions | | |
| Food-related job | Numerical | NAICS sector 72 |
| distributions | | |
| Educational job | Numerical | NAICS sector 61 |
| distributions | | |
| Total job distributions | Numerical | All NAICS sectors |
| Leisure park area | Numerical | Area of leisure park |
| distributions | | (OSM tag “leisure = park”) |
| Shop/errands-related | Numerical | OSM tags “shop = *” |
| POI distributions | | |
| Recreation-related POI | Numerical | OSM tags “leisure = *”, |
| distributions | | “tourism = *” |
| Food-related POI | Numerical | OSM tags “amenity = restaurant”, |
| distributions | | “amenity = fast-food“, |
| | | “amenity = cafe”, “food = *” |
| Educational POI | Numerical | OSM tags “amenity = school”, |
| distributions | | “building = school”, |
| | | “school = *” “amenity-university”, |
| | | “building-university”, |
| | | “university = *” |

In Table 13, OSM tags containing “*” indicates all possible values linked to the specified key. For example, “shop=*” denotes all possible tags associated with the “shop” key. Also, each distribution feature comprises a 6-element vector representing the value regarding different mode-duration levels: 0-5 minutes of walking, 5-10 minutes of walking, 10-15 minutes of walking, 0-8 minutes of biking, 8-13 minutes of biking, and 0-25 minutes of public transit.

FIG. 12A shows the traveler classifier model. In accordance with this model, an individual's traveler type can be deduced from demographic attributes, including age, employment status, education, vehicle ownership, parenthood status, and household income level. The traveler classifier model is trained through the process previously described in conjunction with FIG. 2, which identifies eight distinct traveler types from the NHTS data. Table 14 provides an overview of the derived traveler types. More details about the clustering process can be found elsewhere herein.

FIG. 12B shows the activity count choice model. In accordance with this model, during a particular time-of-day t, an agent may have 0 to 6 activities. The number of activities cₜ is sampled from the probability distribution p(c|h(x′), k) generated by activity count choice model, which is a machine learning classification model.

FIG. 12C shows the activity type choice model. In accordance with this model, for each time-of-day t, following the prior prediction of the total number of activities cₜ, a sequence of activities is generated. Each activity is sampled from the distribution p(a|c, h(x′), k) governed by activity type choice model, which is also a machine learning classification model. Repeating this process for all times-of-day, a complete one-day activity diary s can be generated for each agent.

FIG. 12D shows the mode-duration choice model. In accordance with this model, when making trips, agents start by selecting mode m and duration d. There are four available transport modes: walk, bike, vehicle, and public transit. Each mode is associated with five distinct duration ranges, as described in the “Travel mode-duration range” feature in Table 13. The selection of a specific mode-duration pair is determined by the distribution p(m, d|c, a, h(x′), k) generated from trip mode-duration choice model, another machine learning classification model. Additional details about this model can be found elsewhere herein.

FIG. 12E shows the destination choice model. In accordance with this model, agents select their destination from a set of available blocks that meet the transport mode-duration requirements. Blocks are weighted, and their weight varies depending on the intended activity. For instance, when the intended activity is work, the total job count is considered for weighting. When the intended activity is school, shopping, recreation, or meal, a corresponding subset of jobs and POIs will be used for weighting. Note that recreation activity will further consider green spaces as a weighting factor. Let wₐ(x) denotes the weight of block x for activity a. It can be calculated as follows:

$${w}_{a} ( x ) = \{ \begin{matrix}1 ( x is home ) , & if a = “ home ” \\ \frac{Job ( x )}{{\sum }_{i} Job ( {x}_{i} )} , & if a = “ work ” \\ max ( \frac{{Job}_{a} ( x )}{{\sum }_{i} {Job}_{a} ( {x}_{i} )} , \frac{{Poi}_{a} ( x )}{{\sum }_{i} {Poi}_{a} ( {x}_{i} )} , \frac{Green ( x )}{{\sum }_{i} Green ( {x}_{i} )} ) , & if a = “ recreation ” \\ max ( \begin{matrix}\frac{Job ( x )}{{\sum }_{i} Job ( {x}_{i} )} , \frac{Poi ( x )}{{\sum }_{i} Poi ( {x}_{i} )} , \\ \frac{Green ( x )}{{\sum }_{i} Green ( {x}_{i} )} , \frac{Population ( x )}{{\sum }_{i} Population ( {x}_{i} )}\end{matrix} ) , & if a = “ other ” \\ max ( \frac{{Job}_{a} ( x )}{{\sum }_{i} {Job}_{a} ( {x}_{i} )} , \frac{{Poi}_{a} ( x )}{{\sum }_{i} {Poi}_{a} ( {x}_{i} )} ) , & else\end{matrix}$$

where xᵢ represent the i-th block that meets the requirement and is therefore competing with block x. 1(x is home) denotes the indicator function that yields 1 if x is the home block for the agent, and 0 otherwise. Green denotes green space area, Population denotes total population, Job denotes total number of jobs, Poi denotes total number of POIs, Jobₐ and Poiₐ denotes number of jobs and POIs associated with activity a. The correlation between types of jobs, POIs, and activities is outlined in the description of built environment variables provided in Table 13. Compared to Equation (15), this model is simplified as p(b|a, m, d, h(x′), k), disregarding the impact of activity count on the destination choice.

FIG. 12F shows the route choice model. In accordance with this model, the fastest route connecting the starting and destination block is assigned as the trip route. The routing process is accomplished through a Dijkstra-based algorithm, where travel time serves as the impedance metric. For public transit trips, a separate routing process is employed exclusively on the transit network. Given that transit trips must commence and terminate at transit stops, additional walking trips are generated between the actual origin, destination block, and the transit stops. The routing engine Itinero.net is utilized, which harnesses road metadata from OSM for realistic routing. Compared to Equation (15), this model is simplified as p(r|m, b, h(x′), k), disregarding the impacts of activity count and activity type on the route choice.

TABLE 14
Qualitative description of traveler types.

| | Percent | Most active | | |
|---|---|---|---|---|
| Tra- | in NHTS | time-of-day | Mode | Dominant |
| veler | national | and dominant | pre- | socio-demographic |
| type | dataset | activity types | ference | characteristics |
| C1 | 20% | morning | vehicle | Employed, mid-age, no |
| | | (home, | | child in household, have |
| | | work), evening | | bachelor's degree, |
| | | (work, | | household own vehicle, |
| | | shop/errands, | | small household, |
| | | home) | | mid to high |
| | | | | household income |
| C2 | 8.30% | morning (home, | vehicle | Not employed, |
| | | shop/errands, | | mid-age, have child in |
| | | others), noon | | household, household |
| | | (shop/errands, | | own vehicle, large |
| | | others, home) | | household |
| C3 | 3.30% | morning | vehicle | Not employed, young, |
| | | (home, | | no bachelor's degree, |
| | | school) | | household own |
| | | | | vehicle, large |
| | | | | household, mid to high |
| | | | | household income |
| C4 | 20.20% | morning (home, | vehicle | Employed, mid-age, |
| | | work), afternoon | | no child in household, |
| | | (work, home), | | no bachelor's degree, |
| | | evening (work, | | houschold own vehicle, |
| | | home) | | large houschold |
| C5 | 1.10% | morning (home, | multi- | Employed, mid-age, |
| | | work), evening | modal | no child in household, no |
| | | (work, shop/ | | vehicle, small household, |
| | | errands, home) | | mid to low |
| | | | | household income |
| C6 | 2.30% | morning (home, | multi- | Not employed, mid-age |
| | | shop/errands, | modal | or aged, no child in |
| | | others), noon | | household, no bachelor's |
| | | (shop/errands, | | degree, no vehicle, small |
| | | home) | | household, low household |
| | | | | income |
| C7 | 11.10% | morning | vehicle | Employed, mid-age, |
| | | (home, | | have child in household, |
| | | work, others), | | have bachelor's degree, |
| | | evening (work, | | household own vehicle, |
| | | others, home) | | large household, mid to |
| | | | | high household income |
| C8 | 33.80% | morning (home, | vehicle | Not employed, |
| | | shop/errands, | | aged, no child in |
| | | others, | | household, household |
| | | recreation), | | own vehicle, small |
| | | noon | | household |
| | | (shop/errands, | | |
| | | home) | | |

In Table 14, traveler types are derived from the traveler clustering approach described elsewhere herein. This table only provides a qualitative summary about each cluster. Also, tourists are categorized as C5 and C6, encompassing both business and leisure tourists.

To create the simulation environment, one needs to designate an analysis area of interest, which can take the form of any shape drawn on a map. To accommodate commuting trips to and from distant regions and minimize edge effects, the modeling area should extend beyond the actual area of interest. This supplementary modeling area is referred to herein as a buffer zone, which utilizes a specified size and granularity. The buffer zones in some embodiments are defined as a grid of points with particular grid sizes (e.g., 300 meters, 800 meters, etc.). Data from blocks within the buffer zone is mapped to the grid points using a matching algorithm.

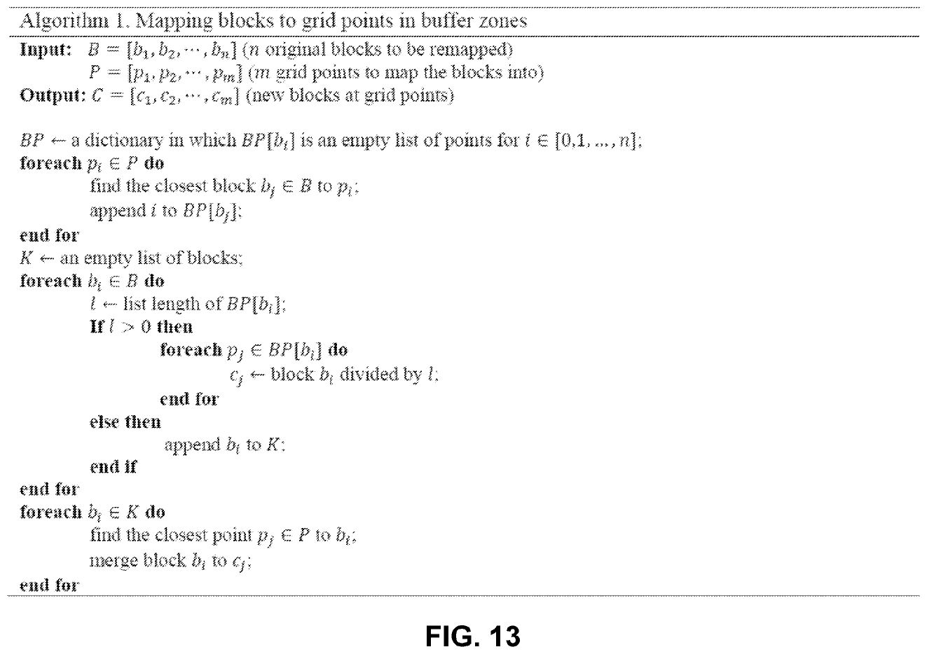

FIG. 13 shows an example of such a matching algorithm, denoted as Algorithm 1. Algorithm 1 takes as its inputs a set B of n original blocks to be remapped and a set P of m grid points to which the blocks are mapped, and generates as its output a set C of m new blocks at the m grid points.

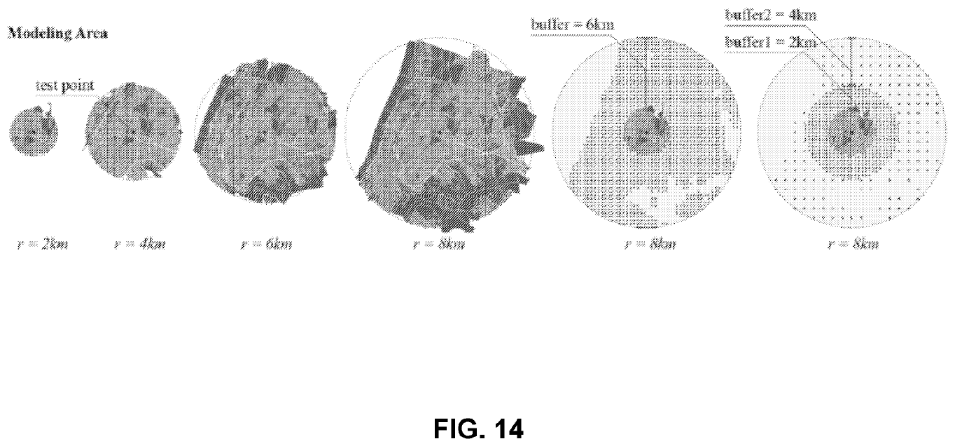

FIG. 14 shows examples of simulation configurations including modeling areas with and without buffer zones in illustrative embodiments. More particularly, in these examples, modeling areas of radius r=2 km, 4 km, 6 km and 8 km without buffer zones are shown. Also, a modeling area with an 8 km radius and a 6 km buffer zone is shown, as well as a modeling area with an 8 km radius and first and second buffer zones of 2 km and 4 km. The buffer zones are defined as a grid of points with grid sizes of 300 meters and 800 meters, respectively. For each of these example modeling areas, simulated pedestrian throughput, simulated biker throughput and simulated vehicle throughput may be generated.

Users can determine the optimal configuration for their specific trade-offs based on the performance analysis.

Once the modeling area has been defined, external data sources can be imported to create blocks, roads, and transit routes. A streamlined workflow is developed to automatically download required data from open datasets. The default data source for roads and transit routes is OSM, while the default block units are census blocks, offering the finest spatial resolution for U.S. Census data.

For each block, the entry point for road access is set as the nearest point on the road network to the block's centroid. Residential population data is extracted from the census data, and job counts are obtained from the LODES dataset. POIs are gathered from OSM and matched to blocks based on their closest point. The tourist population is estimated based on the presence of hotel POIs within the block. Nevertheless, it is important to emphasize that the blocks can take on any user-specified spatial resolution, such as buildings, block groups, or arbitrary grid points, provided that the necessary population, job, and POI data is accessible or is properly mapped to these units.

A specific number of agents are initiated in each block based on the residential and tourist populations. These agents identify their initiation block as their “home” location. The distribution of traveler types within each block is derived from the PUMS dataset using the submodel traveler classifier model. This submodel is used to classify each person in the PUMS dataset to a particular traveler type so that the aggregate distribution of types can then be computed.

It should be noted that, for the sake of computational efficiency, the number of agents may not always equal the actual population size. For instance, one can create just 100 agents to represent a population of 500 individuals, where each agent stands for 5 people. The example method of clustering agents into only eight types allows accurate replication of the population distribution using far fewer agents than traditional population synthesis techniques, which rely on much higher-dimensional demographic breakdowns and therefore need larger sample sizes to achieve the same level of replication.

Illustrative embodiments disclosed herein provide significant advantages relative to conventional approaches.

For example, the disclosed frameworks in some embodiments demonstrate exceptional computational efficiency, accomplishing building or block-level simulations at the neighborhood scale within seconds to minutes and at the mega-city scale in minutes to a few hours, depending on specific configurations. This distinguishes such embodiments from other agent-based mobility simulation tools, which may require days to conduct detailed simulations at urban scales.

Some embodiments provide frameworks that offers enhanced responsiveness to comprehensive built environment factors and socio-demographic variables, thereby providing more informative tools for assessing diverse planning and design schemes.

Additionally or alternatively, the disclosed frameworks in some embodiments exhibit enhanced adaptability and extensibility. Such frameworks allow flexible adjustments in spatial resolution, buffer zones, and model complexity. Additionally, the data-driven nature of the submodels simplifies the inclusion of new variables of interest into the simulation.

These and other advantages described elsewhere herein may be present in some embodiments but not in other embodiments, and therefore should not be viewed as required features of particular embodiments.

It should be understood that the particular arrangements shown and described in conjunction with FIGS. 1 through 14 are presented by way of illustrative example only, and numerous alternative embodiments are possible. The various embodiments disclosed herein should therefore not be construed as limiting in any way. Numerous alternative arrangements of data-driven simulation and analysis frameworks and their associated processing stages and machine learning models can be utilized in other embodiments. Those skilled in the art will also recognize that alternative processing operations and associated system configurations can be used in other embodiments.

It is therefore possible that other embodiments may include additional or alternative system elements, relative to the entities of the illustrative embodiments. Accordingly, the particular system configurations and associated algorithm implementations can be varied in other embodiments.

A given processing device or other component of an information processing system as described herein is illustratively configured utilizing a corresponding processing device comprising a processor coupled to a memory. The processor executes software program code stored in the memory in order to control the performance of processing operations and other functionality. The processing device also comprises a network interface that supports communication over one or more networks.

The processor may comprise, for example, a microprocessor, an ASIC, an FPGA, a CPU, a GPU, a TPU, an ALU, a DSP, or other similar processing device component, as well as other types and arrangements of processing circuitry, in any combination. For example, at least a portion of the functionality of at least one data-driven simulation and analysis framework, and its associated processing stages and machine learning models, as provided utilizing a processing platform comprising one or more processing devices as disclosed herein, can be implemented using such circuitry.

The memory stores software program code for execution by the processor in implementing portions of the functionality of the processing device. A given such memory that stores such program code for execution by a corresponding processor is an example of what is more generally referred to herein as a processor-readable storage medium having program code embodied therein, and may comprise, for example, electronic memory such as SRAM, DRAM or other types of random access memory, ROM, flash memory, magnetic memory, optical memory, or other types of storage devices in any combination.

As mentioned previously, articles of manufacture comprising such processor-readable storage media are considered embodiments of the present disclosure. The term “article of manufacture” as used herein should be understood to exclude transitory, propagating signals. Other types of computer program products comprising processor-readable storage media can be implemented in other embodiments.

In addition, embodiments of the present disclosure may be implemented in the form of integrated circuits comprising processing circuitry configured to implement processing operations associated with a data-driven simulation and analysis framework.

An information processing system as disclosed herein may be implemented using one or more processing platforms, or portions thereof.

For example, one illustrative embodiment of a processing platform that may be used to implement at least a portion of an information processing system comprises cloud infrastructure including virtual machines implemented using a hypervisor that runs on physical infrastructure. Such virtual machines may comprise respective processing devices that communicate with one another over one or more networks.

The cloud infrastructure in such an embodiment may further comprise one or more sets of applications running on respective ones of the virtual machines under the control of the hypervisor. It is also possible to use multiple hypervisors each providing a set of virtual machines using at least one underlying physical machine. Different sets of virtual machines provided by one or more hypervisors may be utilized in configuring multiple instances of various components of the information processing system.

Another illustrative embodiment of a processing platform that may be used to implement at least a portion of an information processing system as disclosed herein comprises a plurality of processing devices which communicate with one another over at least one network. Each processing device of the processing platform is assumed to comprise a processor coupled to a memory. A given such network can illustratively include, for example, a global computer network such as the Internet, a WAN, a LAN, a satellite network, a telephone or cable network, a cellular network such as a 4G or 5G network, a wireless network implemented using a wireless protocol such as Bluetooth, WiFi or WiMAX, or various portions or combinations of these and other types of communication networks.

Again, these particular processing platforms are presented by way of example only, and an information processing system may include additional or alternative processing platforms, as well as numerous distinct processing platforms in any combination, with each such platform comprising one or more computers, servers, storage devices or other processing devices.

A given processing platform implementing a data-driven simulation and analysis framework as disclosed herein can alternatively comprise a single processing device, such as a computer or other processing device. It is also possible in some embodiments that one or more such system elements can run on or be otherwise supported by cloud infrastructure or other types of virtualization infrastructure.

It should therefore be understood that in other embodiments different arrangements of additional or alternative elements may be used. At least a subset of these elements may be collectively implemented on a common processing platform, or each such element may be implemented on a separate processing platform.

Also, numerous other arrangements of computers, servers, storage devices or other components are possible in an information processing system. Such components can communicate with other elements of the information processing system over any type of network or other communication media.

As indicated previously, components of an information processing system as disclosed herein can be implemented at least in part in the form of one or more software programs stored in memory and executed by a processor of a processing device. For example, certain functionality disclosed herein can be implemented at least in part in the form of software.

The particular configurations of information processing systems described herein are exemplary only, and a given such system in other embodiments may include other elements in addition to or in place of those specifically shown, including one or more elements of a type commonly found in a conventional implementation of such a system.

For example, in some embodiments, an information processing system may be configured to utilize the disclosed techniques to provide additional or alternative functionality in other contexts.

It should again be emphasized that the embodiments of the present disclosure as described herein are intended to be illustrative only. Other embodiments of the disclosure can be implemented utilizing a wide variety of different types and arrangements of information processing systems, networks and processing devices than those utilized in the particular illustrative embodiments described herein, and in numerous alternative processing contexts. In addition, the particular assumptions made herein in the context of describing certain embodiments need not apply in other embodiments. These and numerous other alternative embodiments will be readily apparent to those skilled in the art.

What is claimed is:

1. An apparatus comprising:
a processing platform comprising at least one processing device, the processing device comprising a processor coupled to a memory;
the processing platform being configured:
to implement a machine learning based framework for at least one of simulation and analysis relating to multi-modal mobility, the machine learning based framework comprising a plurality of stages, including at least a population synthesis stage and a trip generation stage;
to execute a first machine learning model in the population synthesis stage; and
to execute a second machine learning model in the trip generation stage, the second machine learning model being different than the first machine learning model.

2. The apparatus of claim 1 wherein the first machine learning model comprises a traveler cluster classifier.

3. The apparatus of claim 2 wherein the traveler cluster classifier is configured to derive traveler cluster percentages for each of a plurality of designated spatial units of a given geographic area at least in part by matching sample data to cluster labels.

4. The apparatus of claim 3 wherein the traveler cluster percentages comprise a vector having entries that indicate respective percentages of a population that belong to respective ones of a plurality of clusters.

5. The apparatus of claim 3 wherein the traveler cluster classifier is further configured to generate agents by cluster for each spatial unit.

6. The apparatus of claim 2 wherein the traveler cluster classifier is trained utilizing a training process in which clusters are derived through a dimension reduction and an associated clustering process.

7. The apparatus of claim 6 wherein the clustering process is based at least in part on a temporal mobility choice matrix.

8. The apparatus of claim 1 wherein the second machine learning model comprises a mode-duration choice model.

9. The apparatus of claim 8 wherein the mode-duration choice model comprises a classification model trained to predict mode-duration choice probabilities for a given trip having particular travel features and environment features.

10. The apparatus of claim 9 wherein a given one of the mode-duration choice probabilities comprises a probability that a particular travel mode having a particular duration will be selected by a given agent for the given trip.

11. The apparatus of claim 1 wherein the machine learning based framework further comprises a schedule synthesis stage arranged between the population synthesis stage and the trip generation stage.

12. The apparatus of claim 11 wherein the schedule synthesis stage is configured to generate a sequence of activities for each of a plurality of agents generated by the population synthesis stage and wherein the resulting sequences of activities are sampled based at least in part on cluster centroids output by a training process of the first machine learning model.

13. The apparatus of claim 1 wherein the machine learning based framework further comprises a metric evaluation stage following the trip generation stage.

14. The apparatus of claim 13 wherein the metric evaluation stage is configured to generate one or more analysis outputs in which simulated trips are aggregated over each of a plurality of different dimensions.

15. A computer program product comprising a non-transitory processor-readable storage medium having stored therein program code of one or more software programs, wherein the program code, when executed by at least one processing device comprising a processor coupled to a memory, causes the processing device:
to implement a machine learning based framework for at least one of simulation and analysis relating to multi-modal mobility, the machine learning based framework comprising a plurality of stages, including at least a population synthesis stage and a trip generation stage;
to execute a first machine learning model in the population synthesis stage; and
to execute a second machine learning model in the trip generation stage, the second machine learning model being different than the first machine learning model.

16. The computer program product of claim 15 wherein the first machine learning model comprises a traveler cluster classifier.

17. The computer program product of claim 15 wherein the second machine learning model comprises a mode-duration choice model.

18. A method comprising:
implementing a machine learning based framework for at least one of simulation and analysis relating to multi-modal mobility, the machine learning based framework comprising a plurality of stages, including at least a population synthesis stage and a trip generation stage;
executing a first machine learning model in the population synthesis stage; and
executing a second machine learning model in the trip generation stage, the second machine learning model being different than the first machine learning model;
wherein the method is performed by at least one processing device comprising a processor coupled to a memory.

19. The method of claim 18 wherein the first machine learning model comprises a traveler cluster classifier.

20. The method of claim 18 wherein the second machine learning model comprises a mode-duration choice model.
